(19) United States
(12) Patent Application Publication
(10) Pub. No.: US 2025/0139324 A1
(43) Pub. Date: May 1, 2025

(54) Smart and Real-time Digital Twins for Open, Programmable and Virtualized Wireless Network Systems

(71) Applicant: Northeastern University, Boston, MA (US)

(72) Inventors: Pedram Johari, Medford, MA (US); Tommaso Melodia, Newton, MA (US); Michele Polese, Cambridge, MA (US); Leonardo Bonati, Boston, MA (US); Davide Villa, Boston, MA (US)

(21) Appl. No.: 18/924,579

(22) Filed: Oct. 23, 2024

Related U.S. Application Data
(60) Provisional application No. 63/593,233, filed on Oct. 25, 2023.

(51) Int. Cl. G06F 30/18

(52) U.S. Cl. CPC G06F 30/18

(57) ABSTRACT

Embodiments disclose a computer-implemented system for representing a wireless communications network. The system includes a digital twinning platform including a real-world twin component and a virtual-world twin component representing at least a matching subset of layers of a full stack wireless communications network, and a communications module configured to enable bi-directional flow of data representing state information corresponding to the subset of layers of the real-world component and the virtual-world component.

### RELATED APPLICATION

This application claims the benefit of U.S. Provisional Application No. 63/593,233, filed on Oct. 25, 2023. The entire teachings of the above application(s) are incorporated herein by reference.

### GOVERNMENT SUPPORT

This invention was made with government support under 693JJ3-21-R-000005 awarded by the U.S. Department of Transportation, W911NF-19-2-0221 awarded by the Army Research Laboratory—Army Research Office, and CNS2112471, and CNS1925601 awarded by the National Science Foundation. The government has certain rights in the invention.

### BACKGROUND

Emulation platforms such as wireless network emulators have unique capabilities for faithfully modeling real-world wireless environments in real time and at scale, while guaranteeing repeatability. These emulators are being increasingly used for developing and evaluating new solutions for next generation wireless networks. However, the reliability of the solutions tested on these emulation platforms depends on the precision of the emulation process, model design, and parameter settings, which is often overlooked. One of the main goals of these emulation platforms is to simulate and avoid harmful interference to coexisting communication systems, and this is emphasized when considering systems in which incumbent radios operate mission critical communication links.

### SUMMARY

Embodiments disclosed herein provide for improvement to existing emulation platforms and simulated wireless environment testing. Embodiments provided herein provide unique capabilities for faithfully modeling real-world wireless environments in real time and at scale, while guaranteeing repeatability.

An embodiment is directed toward a computer implemented system for representing a wireless communications network. The system includes a digital twinning platform including a real-world twin component and a virtual-world twin component, representing at least a matching subset of layers of a full stack wireless communications network. The system also includes a communications module configured to enable bi-directional flow of data representing state information corresponding to the subset of layers of the real-world component and the virtual-world component.

In an embodiment, the digital twinning platform includes a modeler configured to generate a model to represent the wireless communications network.

In a further embodiment, the generated model includes: (i) representations of physical surfaces defining a real-world environment of the wireless communications network, and (ii) nodal representations of at least a subset of transmitters, receivers, or transceivers composing the wireless communications network.

In a still further embodiment, the generated model is further configured by the system to be loaded into a ray-tracing program. The ray-tracing program is further configured to assign material properties to at least a subset of the representations of physical surfaces and model the nodal representations and define trajectories of at least a subset of radio frequencies associated with the nodal representations.

In another embodiment, a graphical user interface (GUI) or an application programming interface (API) is configured to enable a user to perform a simulation of channel environments within the digital twin virtual-component of the wireless communications network.

In a further embodiment, the simulation includes at least one controllable parameter within the virtual-world twin component, the GUI and API further configured to push the controllable parameter from the virtual-world twin component to the real-world physical twin component.

In another embodiment, the communications module enables the bi-directional data flow between the real-world physical twin component and the virtual-world twin component to occur in real time.

Another embodiment includes a socket configured to enable at least one feature or part of a real-world device to stand in place of at least one corresponding feature or part of the virtual-world component.

In another embodiment, the digital twinning platform is further configured to track at least one control system configured to host or run a computer code related to a protocol for the full stack wireless communications network, provide at least one pipeline configured to replicate a software built in the virtual-world twin component and real-world physical twin component, and generate the virtual-world twin component representing a corresponding subset of layers of the full stack wireless communications network from the tracked at least one control system and the provided at least one pipeline.

In a further embodiment, the at least one pipeline enables real-time testing of at least one virtual-world component simulation parameter in the real-world twin component, or real-time testing of at least one real-world physical component parameter in the virtual-world twin component.

Another embodiment is directed toward a computer-implemented method for representing a wireless communications network. The method includes twinning a real-world wireless communications network via a digital twinning platform, the digital twinning platform comprising a real-world twin component and a virtual-world twin component representing at least a matching subset of layers of a full stack wireless communications network, and enabling bi-directional flow of data representing state information, via a communications module, corresponding to the subset of layers of the real-world component and the virtual-world component. This method may be configured implement any embodiments, or combination of embodiments, described herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIGS. 1A and 1B illustrate an overview of the interconnection and architecture of a digital twinning platform, according to an embodiment.

FIG. 2 is a flow chart for a method of representing a wireless communications network, according to an embodiment.

FIG. 3 is a block diagram illustrating a software-based channel generator and sounder toolchain, according to an embodiment.

FIG. 4 is a flow diagram summarizing the steps of a software-based channel generator and sounder toolchain for characterizing wireless network scenarios, according to an embodiment.

FIG. 5 is a workflow diagram illustrating the protocol stack twinning process across digital and physical environments, according to an embodiment.

FIGS. 6A-6C are block diagrams depicting an overview of Colosseum architecture.

FIG. 7 is a block diagram depicting an overview of Arena architecture.

FIG. 8 is an example representation of a real-world environment and a digital 3D model of the same environment after the environment has been loaded into a ray-tracing software.

FIG. 9 is a representation of modeled antenna points in Arena.

FIG. 10 is a heat map illustrating path loss amongst transmitters and receivers in Arena.

FIG. 11 is an enlarged view of that of FIG. 9 illustrating a cellular use case as an example.

FIGS. 12A and 12B are plots illustrating User Datagram Protocol downlink throughput for static and mobile nodes in Arena and Colosseum.

FIGS. 13A and 13B are plots illustrating Transmission Control Protocol downlink throughput versus time for an example scenario.

FIGS. 14A and 14B are plots illustrating Signal to Interference-plus Noise Ratio versus time for an example scenario.

FIG. 15 is an enlarged view of that of FIG. 9 illustrating signal jammers for an example scenario.

FIGS. 16A and 16B show plots illustrating two common forms of static jumping in an example scenario.

FIG. 17 is a plot illustrating the impact that a mobile jammer has in an example scenario.

FIG. 18 is a map outlining the location of nodes and a base station, for an example scenario.

FIG. 19 is a plot illustrating a time frame of received path games for an example scenario.

FIGS. 20A-D are four plots illustrating four different code sequences auto correlation against time for an example scenario.

FIG. 21 is a path loss heat map for an example scenario.

FIG. 22 is a plot comparing received path gains versus the original path gains for an example scenario.

FIGS. 23A and 23B are respective plots illustrating path gain over time, the original representation, and the received path gains for an example scenario.

FIG. 24 is a plot illustrating a comparison between the original and received path gains over time for an example scenario.

FIGS. 25A and 25B are respective plots illustrating radar characterization with Power Spectral Density, as well as a constellation plot, for an example scenario.

FIG. 26 is a flow diagram illustrating various operations to integrate an arbitrary waveform into a wireless network emulator, according to an embodiment.

FIGS. 27A and 27B are respective plots illustrating a received radar waveform and the radar correlation for an example scenario.

FIGS. 28A and 28B are a map of Waikiki Beach and corresponding nodes, as well as a 3D model of Waikiki Beach and corresponding nodes, for an example scenario.

FIG. 29 is a heat map of the path loss among each pair of nodes after channel approximation is completed, for an example scenario.

FIGS. 30A and 30B are respective plots illustrating the performance of a cellular network in an example scenario.

FIG. 31 is a plot illustrating the effectiveness of a detector in understanding the presence of a radar signal, in an example scenario.

FIG. 32 illustrates a computer network or similar digital processing environment in which embodiments of the present disclosure may be implemented.

FIG. 33 is a diagram of an example internal structure of a computer in the computer system of FIG. 32.

### DETAILED DESCRIPTION

A description of example embodiments follows.

Embodiments relate to improvements to wireless emulation platforms and provide the ability to construct a digital twin (DT) of a physical wireless network by twinning the physical environment, the radio networks, and the protocol stack. This enables a user to perform simulations within the digital twin and to push settings and changes performed within the simulation to the physical wireless network. This can dramatically reduce the cost associated with testing and implementing changes to existing wireless networks. These embodiments may be referred to herein as Digital Radio Access Networks, or “DigiRAN.” Following a description of embodiments presented herein, testing results and validation of embodiments are presented.

Specifically, embodiments operationalize a high-fidelity wireless network digital twining platform with hardware-in-the-loop. This provides a framework designed to streamline low-cost, real-time, repeatable, and automated testing and evaluation of the interoperability, performance and security for Radio Access Networks (RAN), in a heterogeneous, emulated, testing environment. These embodiments were developed based on pipelines designed to streamline dynamic Open RAN wireless network scenarios created and deployed on a wireless network emulator. The wireless network emulator primarily utilized herein is referred to as “Colosseum,” and is utilized as the wireless network digital twin.

The pipelines guarantee high fidelity radio frequency emulation scenarios, automated protocol stacking twinning, and integration of commodity hardware-in-the-loop with the digital twin. Embodiments provide for the first time an automated and virtualized end-to-end testing and evaluation environment that allows open and interoperable standards-based RAN components to be tested individually (i.e., disaggregated components, cell units, distributed units, and radio units), or in an end-to-end integrated fashion at a fraction of the cost compared to what is today possible in plugfests and similar events.

Wireless network operators have estimated that in order to drive-test nationwide coverage it would cost millions of dollars each year. Conducting these tests, especially on a regular basis, is simply too costly, especially at a time when investment in open and interoperable 5G network testing and deployment is a top priority. Solution development and testing of next generation wireless networks are in fact evolving toward integrating actual network systems within a digital model that provides a replica of the physical network, i.e., a digital twin, to be used for continuous prototyping, testing, and self-optimization of the link network.

In the context of Open RAN, the digital twin enables the network providers to check different networking scenarios for network planning, optimization and monitoring, among other use cases, in a risk-free environment without interrupting the operations of the real network.

For example, for network planning, different topologies and configurations can be assessed along various “what-if” scenarios (e.g., traffic loads and multi-vendor interoperability), before implementing to real networks. These processes help identify whether networks require an upgrade to meet the demands of a likely situation. Digital twins can also be leveraged in network monitoring and real time anomaly detection when the network deviates from its normal operations, or to predict any service disruptions before they even happen. While traditional physical testing typically requires extensive coordination and resources to bring together equipment from different vendors, which can often be time consuming and expensive, high fidelity digital twins such as those provided by embodiments disclosed herein enable efficient and repeatable testing of multi-vendor interoperability, performance and security at a fraction of cost. This can significantly accelerate the integration and testing processes with more flexible test plans (e.g., environments, and different stages of 5G product development), while maintaining suitable test accuracy.

Digital twins may be defined as (i) a physical product in the real-world, (ii) a virtual representation of the product in the virtual-world, and (iii) a connection of data and information tying the two. DigiRAN allows for a set of tools to create and validate a comprehensive digital representation of a particular real-world system inside a virtual environment. This enables researchers to run wireless experiments inside a DT of virtually any type of physical environment; develop and test new algorithms; and derive results as accurately and as close as possible to the behavior that they would obtain in the real-world environment.

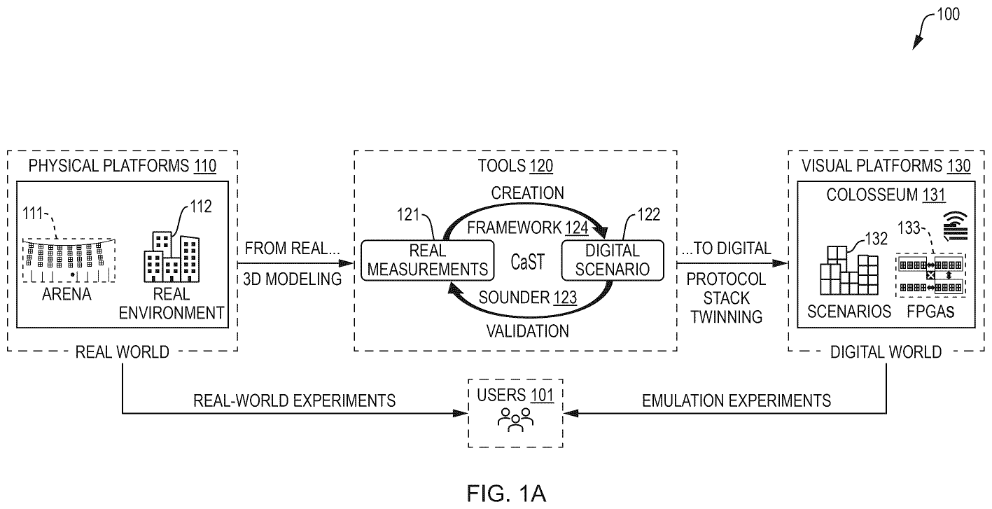

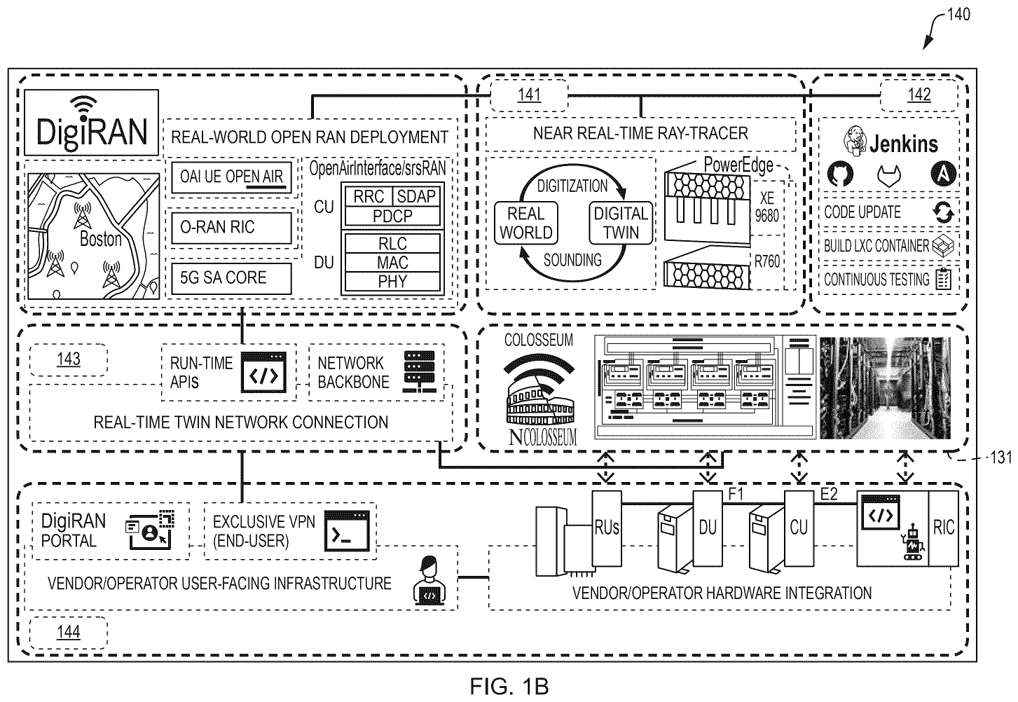

FIGS. 1A and 1B illustrate an overview of the DigiRAN interconnection architecture and main components. FIG. 1A shows a flow diagram 100 illustrating a high-level overview of the main components of the digital twinning platform, according to an embodiment. The physical platforms 110 and the virtual platform 130 are twinned and linked, in part, by a validation tool “Channel emulation scenario generator and Sounder Toolchain” 120 referred to as “CaST” described in detail below. The physical platforms 110 may include real-world environments 112, for example a city street, a harbor side, the inside of an office building, etc. Also included in the physical platforms 110 is “Arena” 111, which is an indoor office space utilized for the validation and testing of embodiments implemented herein and likewise described below. The virtual platforms 130 refer to the digital twin of the physical platforms, i.e., the digitized virtual environment including transmitting nodes, receiving nodes, physical surfaces and their respective reflectance properties. Colosseum 131 is an existing large scale emulation platform; a detailed description of Colosseum is described blow. However, in short, Colosseum includes scenarios 132, which may be testing scenarios, as well as a series of field programmable gate arrays (FPGA) 133 that emulate the scenarios. In order to replicate the radio access networks in addition to the physical properties of the real environment, the radio access networks from the physical platforms 110 are also digitized and twinned by using CaST 120 in order to implement them in the virtual platforms 130. This involves taking real measurements 121 of the radio access networks from the real-world, pushing them through the CaST framework 124 so that they may be present in the digital scenario 122, and then validating the digital scenario 122 through a sounder network also implemented in CaST 120. This allows the user 101 to perform digital testing within the virtual platforms 130 in a realistic setting emblematic of the physical platforms 110 quickly and efficiently and without any risk to existing networks or hardware.

FIG. 1B shows a high-level overview 140 of the interconnection of different aspects and steps of the DigiRAN embodiments. The first step 141 in DigiRAN embodiments is to open a RAN wireless network emulation scenario for the digital twin. This step involves the utilization of pipelines that allow end users of the testbed to generate radio frequency (RF) emulation scenarios from channel characterization they've previously performed (CaST) and to generate radio frequency scenarios on the fly through graphical processing unit (GPU) based ray-tracing that integrates into the system as well as perform dynamic RF emulation scenarios to introduce statistical variations in the execution of already existing Colosseum scenarios.

The second step 142 is to open RAN automated protocol stack twinning. This expands on the capabilities of Colosseum to allow end users to twin custom protocol stacks in the testbed, enabling them to evaluate real-world solutions in the controlled setup through automated tools. After validation of the digital twin in the controlled environment to ensure tested components behave as expected, solutions can be moved and used in the physical twin.

The next step 143 is to enable real time connection between physical and digital twins via pipelines. In the context of digital twinning, the connection between the physical and digital twins adds another layer of realism and sophistication to the emulation process. By streaming key performance indicators (KPIs) between the twins, it becomes possible to monitor the performance of real-world environments in real time and de-risk decision making operations by first safely testing them on the digital environment.

The next step 144 is the integration of multi-vendor commodity equipment within DigiRAN embodiments. In this section, Open RAN equipment from multiple vendors is integrated within DigiRAN and offered to streamline procedures for testing functionalities and interfaces. This enables the testing of equipment as part of a larger and integrated network, rather than simply relying on single purpose unit testers that can hardly capture the complex interactions with the larger ecosystem.

These embodiments are operationalized by a developed pipeline for creating and evaluating a virtual wireless world through fast ray-tracing tools 141 with near real time updates between the physical and digital twins 143, as well as an automated protocol stack twinning framework 142 for testing of standards based 5G radio access networks, and a real time networking infrastructure 144 enabled between the real and virtual-world with application programming interfaces (APIs) to test fidelity across the twins. Further, embodiments utilize a developed platform for seamless integration of commodity open RAN units to the digital twin emulation system in order to perform required performance, security, and interoperability testing.

The objective of these embodiments is to implement a scalable and repeatable testing method enabled by wireless network digital twins in order to adjust the multi-vendor interoperability integration and other challenges in Open RAN systems. Embodiments explore how digital twins can facilitate the testing and validation of different units of Open RAN, including radio units (RU), deserted units (DU), and central units (CU), along with their corresponding interfaces.

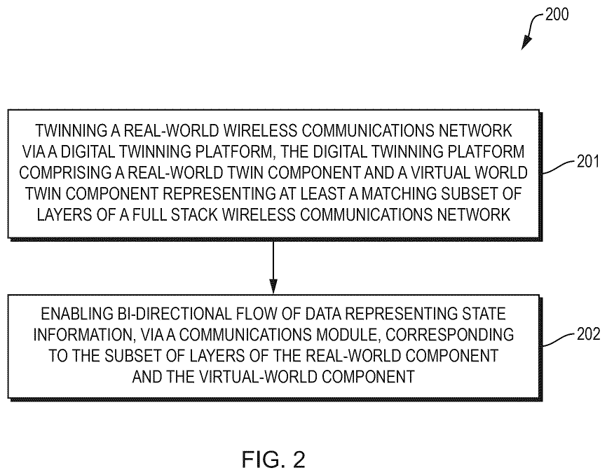

FIG. 2 is a flow chart of a method 200 for representing a wireless communications network, according to an embodiment. The method begins at step 201 by twinning a real-world wireless communications network via a digital twinning platform, namely, DigiRAN. DigiRAN includes a real-world component, as well as a virtual-world twinned component of the real-world. The virtual twin represents at least a matching subset of layers of a full stack wireless communications network existing in the real-world. Further, the digital twinning platform may include generating a model (a three-dimensional (3D) model) of a real-world system and environment to represent the wireless communications network in the digital domain. This generated model may include modeled representations within the digital twin of physical surfaces of the real-world, as well as nodal representations of transmitters, receivers, or transceivers composing the wireless communications network. To further refine the model, according to an embodiment, the model may be loaded into a ray-tracing program, for example but not limited to MATLAB. The ray-tracing program may assign material properties, such as surface reflectance values, to at least a subset of the physical surfaces represented in the model. In addition, the ray-tracing program may model the nodal representations and trajectories of at least a subset of the radio frequencies associated with the nodal representations. According to an embodiment, this model may also perform a simulation of channel environments within the digital twin via a graphical user interface (GUI) or an API.

Next, at step 202, the method enables bi-directional flow of data via pipelines, i.e., between the real-world and virtual-world twin, representing state information via a communications module. The data may correspond to a subset of layers of the real-world component, as well as the virtual-world component. In an embodiment, the bi-directional flow of data may occur in real time. The method 200 may also include a socket configured to enable at least one feature or part of a real-world device, such as commercial hardware integrated within the DigiRAN emulation platform, to stand in place of at least one corresponding feature or part of the virtual-world component.

According to an embodiment, the digital twinning platform may also include tracking at least one control system configured to host or run a computer code related to a protocol for the full stack wireless communications network, providing at least one pipeline configured to replicate a software built in the virtual-world and real-world component, and generating the virtual-world component representing a corresponding subset of layers of the full stack wireless communications network from the tracked control system and the provided pipeline. This may enable the method 200 to provide real time testing of at least one component or simulation parameter in the virtual twin within the physical wireless network, or vice versa.

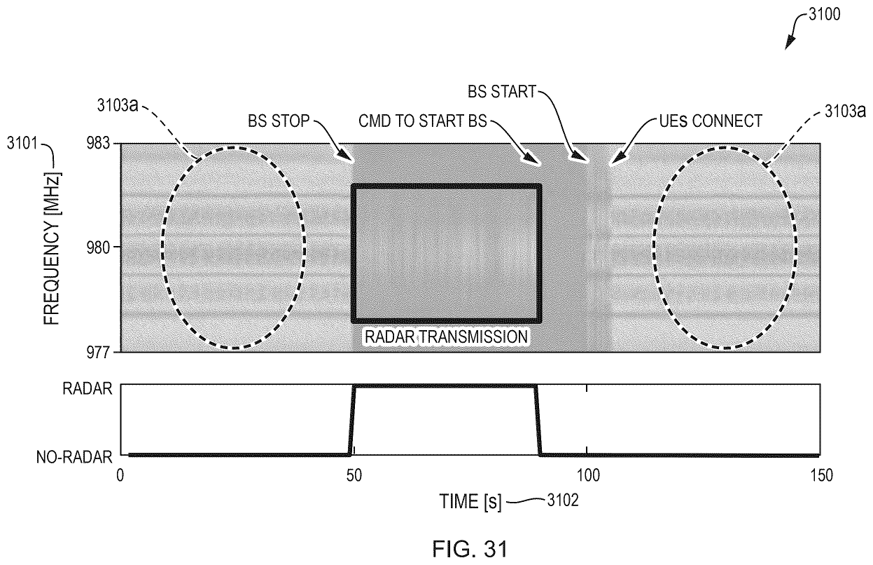

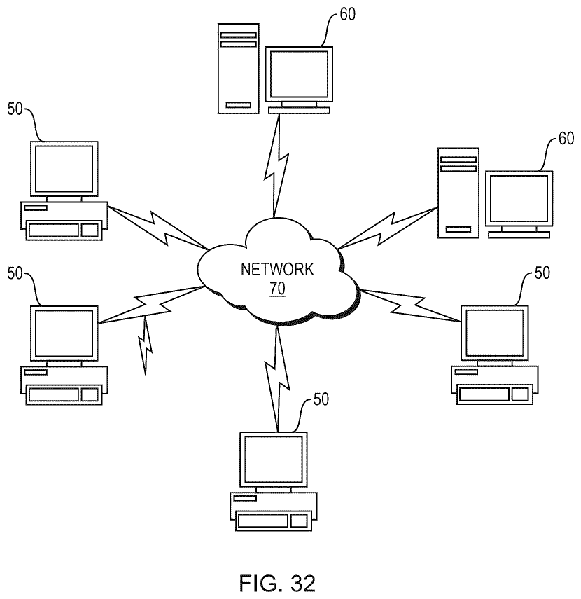

The method 200 is computer-implemented and, as such, the functionality and effective operations, e.g., the twinning (201), and enabling (202), are automatically implemented by one or more digital processors. Moreover, the method 200 can be implemented using any computer device or combination of computing devices known in the art. Among other examples, the method 200 can be implemented using computer(s)/device(s) 50 and/or 60 described hereinbelow in relation to FIGS. 31 and 32. Moreover, the method 200 and embodiments described herein may be implemented in computer-based software.

### Channel Emulation Scenario Generator and Sounder Toolchain “CaST”

The Channel emulation generator and Sounder Toolchain (CaST) for creating and characterizing realistic wireless network scenarios with high accuracy for the DT includes: (i) a framework for generating mobile wireless scenarios from ray-tracing models for FPGA based emulation platforms, and (ii) a containerized software defined radio-based (SDR) channel sounder to precisely characterize the emulated channels. Testing results and implementation of CaST is described below.

As stated above, the reliability of the solutions developed in emulated platforms depends greatly on the precision of the emulation process and of the models of the environment. Most channel emulators are based upon Finite Impulse Response (FIR) filters with predefined complex valued taps that represent the characteristics of this channel, as the Channel Impulse Response (CIR) in the baseband. Additional complexity is added by multipath scenarios with mobile nodes such as Vehicle-to-Everything (V2X) and Unmanned Aerial Vehicles (UAV) communications, which are relevant to next generation networking.

Validation of emulated channel characterization is often neglected and committed to be true as defined by the model parameters. It is therefore necessary to appropriately evaluate the implementation of the channel models, measure potential emulation errors, and to use the finding to further develop corrective measures to compensate for deviations from desired and expected behaviors.

CaST is a SDR based toolchain designed to streamline the generation and validation of virtually any type of wireless environment that can be implemented into wireless network emulators scale. CaST brings to the wireless network emulator landscape a fully open, virtualized and software-based channel generator and sounder toolchain. CaST presents the ability to create realistic wireless scenarios with mobility support and precise ray racing methods for FIR based emulation platforms, as well as providing an SDR-based channel sounder to precisely characterize emulated RF channels, with an accuracy of up to 20 ns (nanoseconds) in sounding CIR tap delays, and a 0.5 dB (decibel) accuracy in measuring tap gains.

Wireless network emulators such as Colosseum, described herein below, do not involve communicating over the air. The RF medium is emulated by means of FIR-based filter taps in the baseband. In this context, the main purpose of channel sounding is validating channel emulation traces rather than acquiring physical environment characteristics. Consequently, the results of the sounding are compared with the original desired channel model that is given to the network simulator as input. These input channel models can be created by different tools, including statistical channel modeling software, ray-tracers, or real-world measurements.

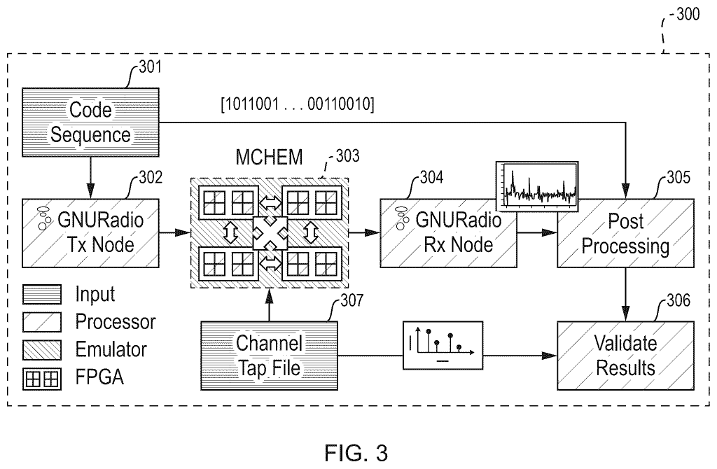

FIG. 3 shows a block diagram 300 illustrating the CaST channel sounding workflow block diagram 300. The CaST channel sounder includes two types of nodes: a transmitter 302, which sends a known code sequence 301 used as a reference for the channel sounding operations, the emulation platform 303 (Massive Channel Emulator (MCHEM) in Colosseum, described below) and one more receivers 304. The nodes are developed using the open source “GNU Radio” open source SDR development toolkit, which enables the design and implementation of software radios through signal processing blocks via hardware or software in-the-loop. The transmitted sequence and the received data are stored and then post-processed 305 using, for example, MATLAB and Python, to obtain channel characterization parameters. Finally, the results are validated 306 and compared with the original CIR 307.

The transmitter 302 takes its input a known code sequence 301 and transmits it to the receiver node 304 through the wireless channel emulated by the Colosseum digital twin through the RF scenario to evaluate. The transmitted signal is composed of sequential repetitions of the code sequence 301 encoded through a binary phase shift keying (BPSK) modulation. While other modulation types are not restricted, BPSK offers sufficient channel information sounding on Colosseum. Additionally, BPSK allows for simple data computations that are less susceptible to errors and approximations, in a cleaner and less disrupted signal. Data is streamed to the Universal Software Radio Peripheral (USRP) controlled by the Standard Radio Node (SRN) that transmits it to the receiving node through the MCHEM. For increased flexibility of the channel sounder, CaST allows users to set various parameters of the USRP, such as clock source, sample rate, and center frequency.

The transmitter node 302 in CaST is designed as a GNU Radio flowgraph with the main duty to build the sequence code and to send it to the receiver 304 via Colosseum's MCHEM 303 (described below). The second table is built upon a vector source block that streams a vector based on an input sequence code 301 and repeats it indefinitely. BPSK modulation is considered where the real part is given by the vector source and transformed into a series of {−1, 1}, while the imaginary part is given by a null source. This stream of data can be displayed through a series of “QT Graphical User Interface” (QT GUI) blocks, or similar, to show time, frequency, and constellation plots of the signal, and is input to a USRP Hardware Driver (UHD) Sink Block. The ladder block sends the GNU Radio software to a USRP hardware device and streams the data with different parameters, e.g., clock source, cost, sample rate, and center frequency. The signal is then transmitted by the USRP to the MCHEM 303.

The receiver node 304 receives and stores the data from the MCHEM 303. The signal is received via a UHD: USRP Source block that streams samples from a USRP hardware device to the GNU radio software. The USRP acts as a receiver with appropriate parameters, e.g., clock, sample rate, and center frequency. The received data can be displayed through a series of QT GUI blocks, and are saved using a file sync block for further post processing. Since this operates in a controlled enclosed environment without any over the air transmissions, there is no need to perform any additional control or filtering of the output bandwidth of transmitted signal to comply with Federal Communications Commission (FCC) regulations. Moreover, the MCHEM 303 filters the unwanted signals that are received, leaving only the frequencies of a particular scenario that is running. Therefore, the transmitter 302 and receiver 304 nodes can be composed of simple yet efficient structures that optimize the channel sounding process and eliminate undesired artifacts

At the receiver 304 side, the SRN USRP samples the signal sent by the MCHEM 303, also known as the transmitted signal processed with the channel taps of the emulation scenario. This signal is cross correlated with the originally transmitted known code sequence 301 to extract the CIR or h(t) of the emulated scenario, and the Path Loss (PL) or p(t). The CIR is used to obtain the time of arrival (ToA) of each multi-tap component of the transmitted signal, which allows measuring the distance between taps, while the PL allows measuring the intensity and attenuation of such components as a function of the time delay.

Let c(t) be a known code sequence of N bits used by the transmitter node, and s^{IQ}(t) be the modulated transmitted sequence with its In-phase and Quadrature (IQ) components. Similarly, let r^{IQ}(t) be the raw IQ components stored by the receiver node. The CIR IQ components can be computed by separately correlating r^{I}(t) and r^{Q}(t) of the received data with the I or Q components of s(t) divided by the inner product of the modulated transmitted sequence with its transpose, as shown in Equations (1) and (2) below:

$${h}^{I} ( t ) = ( {r}^{I} ( t ) ⊗ {s}^{I} ( t ) ) / ( {s}^{{I}^{T}} ( t ) * {s}^{I} ( t ) ) \qquad ( 1 )$$

$${h}^{Q} ( t ) = ( {r}^{Q} ( t ) ⊗ {s}^{Q} ( t ) ) / ( {s}^{{Q}^{T}} ( t ) * {s}^{Q} ( t ) ) \qquad ( 2 )$$

where ⊗ is the cross correlation between two discrete-time sequences x and y which measures the similarity between y and the shifted (lagged) repeated copies of y as a function of the lag. Note that if the considered modulation is BPSK, the denominator will be equal to the length of the equation. The amplitude of the CIR can be obtained by Equation (3) below:

$$\vert h ( t ) \vert = \sqrt{{( {h}^{I} ( t ) )}^{2} + {( {h}^{Q} ( t ) )}^{2}} \qquad ( 3 )$$

and the magnitude of the path gains can be calculated and Equation (4) below:

$${G}_{p} ( t ) [ dB ] = 20 {log}_{10} ( \vert h ( t ) \vert ) - {P}_{t} - {G}_{t} - {G}_{r} \qquad ( 4 )$$

where P_{T} is the power of the transmitted sequence, and G_{T} and Gᵣ are the gain of transmitter and receiver amplifiers all in decibels, respectively. The PL of each multipath can be retrieved by looking at the maximum of Gp(t) in a certain window where a signal of the multipath is received.

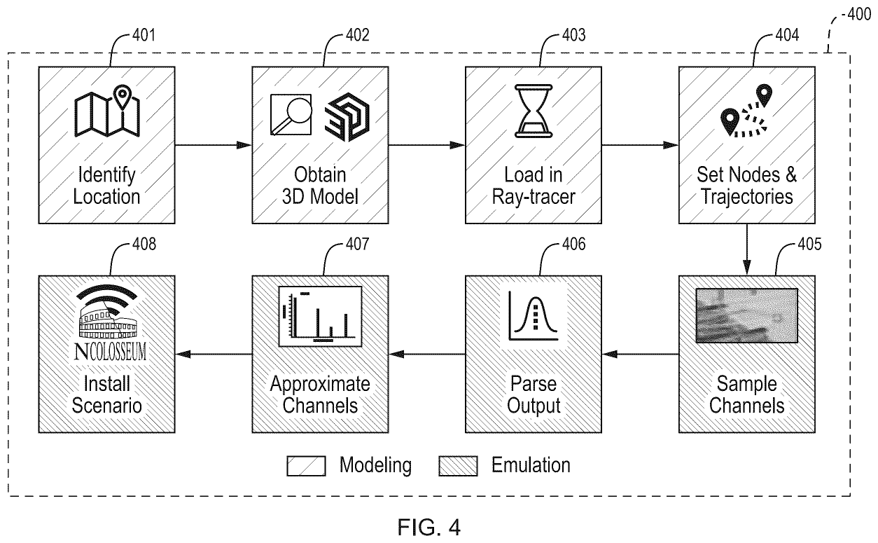

FIG. 4 is a flow diagram 400 summarizing the steps of CaST for characterizing realistic wireless network scenarios. The first step 401 is to identify a physical location to characterize the wireless network—this could be a town, a particular street, an office park, etc. The next step 402 is to obtain a 3D model of the environment. This could be done, for example, through Open Street Map (OSM) or similar. Next, the 3D model is loaded into a ray-tracing software 403, such as MATLAB®. The 3-D model obtained in the previous step 402 needs to be converted into a file format (for example, STL) suitable to be loaded 403 into a ray-tracing software, for example, the MATLAB ray-tracer or Wireless Insight (WI). Each object in the 3-D model imported by the ray-tracing software includes surfaces, and the material properties of these surfaces should be set to have reasonable rates racing results. The ray-tracing software 403 should assign reflectance values to the surfaces contained within the 3D model, in order to accurately capture and recreate the physical network environment of the identified location 401. Similarly, the transmitter/receiver nodes require their radio trajectories to be specified in step 404. Steps 401 through 404 represent the “modeling” portion of the CaST workflow.

Once the 3-D model of the environment has been loaded 403 into the ray-tracing software and the material properties are assigned, the radio nodes need to be modeled 404, which includes setting the nodes' radio parameters, modeling the antenna pattern, and defining locations of the nodes in the physical environment. These nodes can either be static or mobile, in which case their trajectories and movement speed need to also be defined. The radio parameters of the nodes, for example the carrier frequency, bandwidth, transmit power, receiver noise figure, ambient noise density, and antennae characteristics need to be set as well.

At this point, the channel is sampled 405 through the ray-tracing software with the predefined sampling time interval Tₛ, which allows for capturing mobility of the nodes in a discreet way. To this aim, the new trajectories are spatially sampled with a spacing Dᵢ=Vᵢ*Tₛ, where Vᵢ is the speed of notified. Since spatial consistency plays a key role in providing a consisting correlated scattering environment in the presence of mobile nodes, 3^{rd} Generation Partnership Project (3GPP) recommendations were followed and considered coherence distance of 15 m to guarantee an apt spatial consistency.

The next step includes parsing 406 the ray tracer outputs to extract a synchronized channel between each pair of nodes in the scenario for each time instant t spaced at least one millisecond (ms). The temporal characteristic of the wireless channel is considered as a FIR filter, where the CIR is time variant and expressed by Equation (5) below:

$$h ( t , τ ) = {\sum }_{i = 1}^{{N}_{t}} {\tilde{c}}_{i} ( t ) \cdot δ ( t - {τ}_{i} ( t ) ) \qquad ( 5 )$$

where Nₜ is the number of paths at time t, and τᵢ and cᵢ are the ToA and the path gain coefficient of the i-th path, respectively. The latter is a complex number with magnitude aᵢ and phase φ_{I} shown by Equation (6) below:

$${\tilde{c}}_{i} ( t ) = {a}_{i} ( t ) \cdot {e}^{j {φ}_{i} ( t )} \qquad ( 6 )$$

The CIR characterized in the previous steps needs to be converted in a format suitable for MCHEM and FPGA, for example, the 512 channel taps, for which assume nonzero values, spaced with steps of 10 ns and with a maximum access delay of 5.12 microseconds (μs). To do this machine learning-based clustering technique is used to reduce the taps found by the ray-tracing software, align the traffic delays, and finalize their dynamic range, while ensuring the accuracy of the emulated scenario.

Finally, the channel taps resulting from the previous steps are fed the Colosseum scenario generation toolchain, which converts them into FPGA friendly format and installs 408 the resulting RF scenario on the digital twin, ready to be loaded on demand by the RF scenario server. Steps 405-408 represent the “emulation” portion of the CaST workflow.

The twinning of protocol stacks from real to virtual environments (and back) is key in the digital twin ecosystem, as it allows users to swiftly transfer and evaluate real-world solutions in a controlled setup through automated tools. Twining at the protocol stack level, combined with the radio frequency scenario twining, makes it possible to seamlessly prototype, test, and transition end to end full stack solutions for wireless networks to and from digital and physical worlds. After validation in the controlled environment of the digital twin, to make sure what was tested works as expected, the protocol stack solutions can be transmitted back to real-world deployments where they are ultimately used under production network.

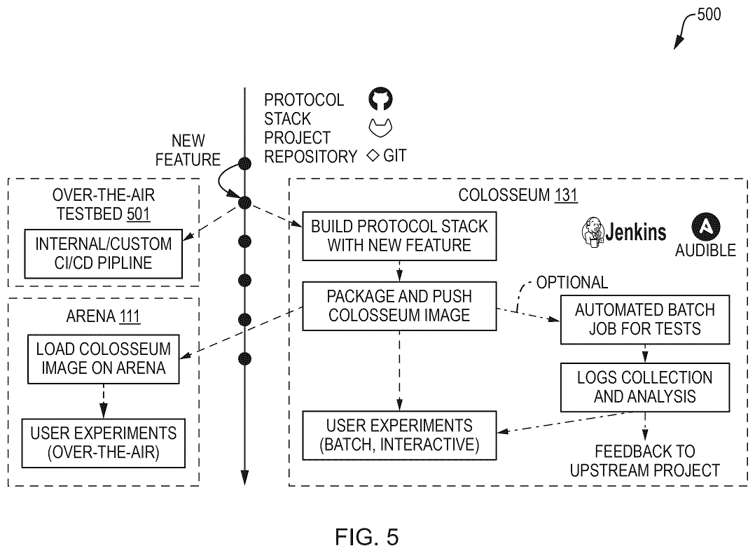

FIG. 5 shows a workflow diagram 500 illustrating the protocol stack twinning process across a digital environment, i.e., Colosseum 131, as well as two physical environments 501 and 111. At a high level, protocol stack twinning involves tracking one or multiple remote centralized version control systems that host the code of the protocol stack and providing pipelines that can automatically replicate the same software built in the digital and physical domains. In addition, it's possible to embed automated steps for the performance validation, i.e., profiling of relevant performance metrics. FIG. 5 illustrates how the protocol stack twinning can be implemented in Colosseum 131, with extensions to a generic over the air testbed 501 and the specific integration with the Arena 111 testbed (discussed below). FIG. 5 refers to a project repository for a sample protocol stack, hosted on a versioning platform that supports the git version control system. This twinning builds on pipelines that already exist to manage Continuous Integration/Continuous Delivery (CI/CD) operations in Colosseum that may be used to monitor changes to repositories of interest, and to trigger an automated code build process in the digital twin domain.

These pipelines monitor the remote code repository of the protocol stack to twin orchestrate the kickoff of the build job, as well as apply relevant configuration parameters to the machine that actually execute the build job. Once the build is successful, the pipelines package the output of the process into a container image (for example, a Linux container image) which is stored on the Colosseum network attached storage, that can be used for testing of the selected functionalities on hardware components from different vendors. Protocol stack twinning facilitates the development of artificial intelligence (AI) or machine learning (ML) solutions. These solutions need to be trained and tested on up-to-date software components, and on a variety of different network conditions and scenarios to be effective once deployed on the physical plane. This also ensures that these applications are trained on realistic data, thus enhancing the applicability and accuracy of the models, as they expose intricacies and nuances of operational networks, and with hardware from different vendors.

### Colosseum

Colosseum is a massive RF and computational facility that emulates wireless signals traversing space and reflecting off multiple objects and obstacles as they travel from transmitters to receivers. As such, it can create virtual-worlds as if the radios were operating an open field, downtown area, shopping mall, or desert, by generating more than 52 terabytes (TB) of data per second.

At a high level, Colosseum comprises two tightly interacting blocks: a set of 128 SDR sources, called standard radio nodes (SRNs), each containing two RF front ends and abundant computational capabilities, as well as a MCHEM, which is also equipped with 128 SDRs. In a nutshell, Colosseum is based on the following main operations. The SRNs are tasked with generating up to 128×2 customized RF full stack waveforms, which are then transmitted over the wire and received by an additional set of 128 radio receiver instruments (RRIs). The MCHEM provides repeatable, real-time, large-scale channel emulation by concurrently processing up to 256×256 (full mesh) interactions between the SRN and the RRIs, thus enabling the emulation of wireless networks composed by up to 256 wireless devices operating concurrently.

Colosseum MCHEM supports time variant channels with minimum coherence time of 1 ms. These channels are read from a tap file that include FIR complex coefficient values for each pair of nodes in a scenario captured every 1 ms for the entire duration of any particular scenario. To facilitate supporting various platforms into Colosseum, the mobile scenario generation process is divided into two tasks. The first is a scenario generator tool chain (CaST), and the second is the mobile channel simulator. CaST installs the scenario on Colosseum and incorporates the RF channel data and the traffic metadata into the scenario, and defines a unique scenario identifier (ID). On the other hand, the mobile channel simulator estimates the channels between the mobile nodes using electromagnetic ray-tracing simulator, and implements the movement of the radio nodes in the ray-tracing radio frequency environment. The mobility simulator is implemented on top of a commercial ray-tracing software, for example Wireless InSite, having of two steps. The first is sampling the mobile channel using the ray tracer, and parsing ray-tracing outputs to extract the channels for each time instant of emulation. These steps are followed by a channel approximation process that is required to adapt the output channels for emulation.

Colosseum's capabilities have been extended through the integration of new computing capabilities for artificial intelligence and machine learning, as well as new emulation modes. The AI equipment includes, for example and as shown herein, two nodes including several GPU's and central processing units (CPUs), as well as random access memory (RAM) and network cards capable of sustaining a high throughput. In addition, a large memory node enables memory intensive workloads. These machines are connected to a dedicated switch, which can sustain an aggregated traffic of up to 16 TB per second. The system may be fully meshed with the computer and wireless resources of Colosseum, with dedicated nomad-based orchestration and load-balancing capabilities.

As mentioned above, Colosseum was used to develop the high-fidelity wireless network twinning platform with integration of commodity hardware in-the-loop to the channel emulation system (CasT). This offered a unique opportunity to accurately emulate and replicate the behavior of Open RAN units and their interfaces in a virtual environment, and to enable repeatable multi-vendor performance and interoperability testing at scale. With the aid of these embodiments, the need for “real life” testing environments may be reduced all together. Instead, a virtual representation of the wireless world combined with the actual Open RAN units and their interfaces is implemented, allowing for rapid and scalable testing in virtually any physical environment of interest.

For the testing and implementation of embodiments described herein Colosseum was used as a Digital Twin for Mobile Network (DTMN) for a real-world wireless experimental testbed. “Arena,” another digital twinning platform described below, was also used for over-the-air-real-world experimentation. By using Colosseum as a DTMN, it allows for the creation of an emulated DT of virtually any real-world wireless scenario in Colosseum, validation of the emulated environment through channel sounding, performed by CaST, and for the twinning of a standardized protocol stack through a CI/CD framework.

Colosseum is capable of twinning both the real and digital worlds by capturing conditions of real environments and reproducing them in a high-fidelity emulation. This is done through RF scenarios that model the characteristics of the physical world (e.g., channel effects, propagation environment, mobility, etc.) and converting them into digital emulation terrains to be used for wireless experimentation. In addition, Colosseum can twin the protocol stack itself, i.e., it allows the deployment of the same generic software-defined stack that can replicate the functionalities of real-world wireless networks.

Through the utilization of these scenarios and the twinning of protocol stacks and generic waveforms, users can collect data and test solutions in many different environments representative of real-world deployments, and fine-tune their solutions before deploying them in production networks to ensure they perform as expected. This allows users to retain full control over the digitized virtual-world, to reproduce all, and solely, the desired channel effects, and to repeat and reproduce experiments at scale.

To enable RF twinning between physical and digital worlds in Colosseum, CaST may be utilized for the creation and characterization of realistic wireless network scenarios with a high degree of fidelity and accuracy. The protocol stack twinning is enabled by a CI/CD platform that can deploy a desired version of a protocol stack in the Colosseum system.

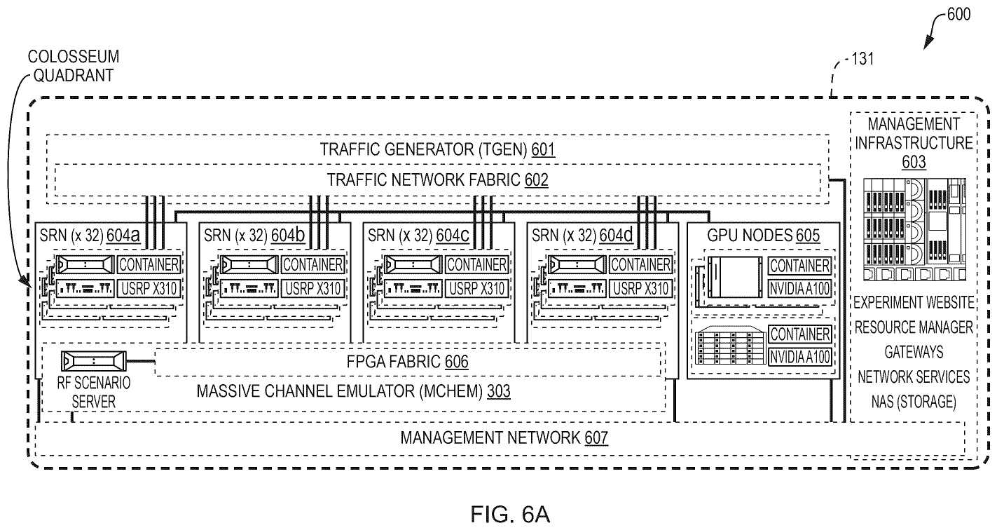

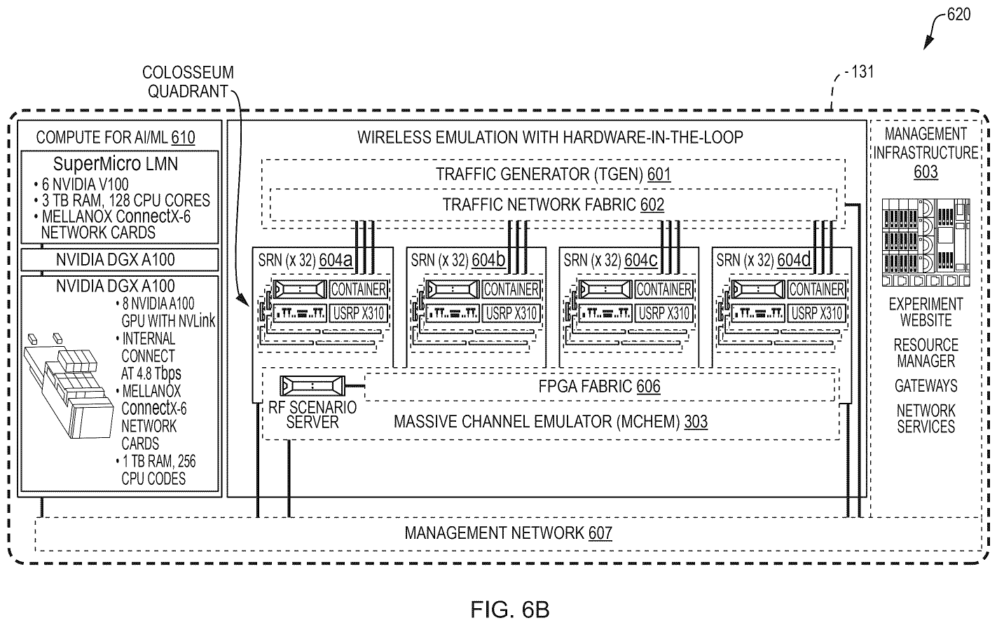

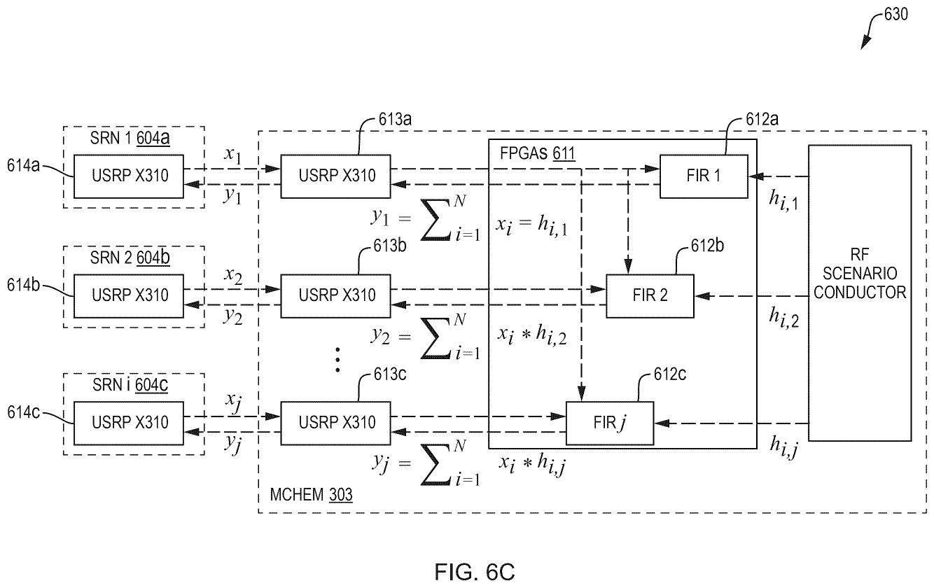

FIGS. 6A-6C show block diagrams 600, 620, and 630, respectively, depicting an overview of the components of Colosseum 131. Diagram 600 of FIG. 6A illustrates the five main components of Colosseum, (i) 128 Standard Radio Nodes (SRN) 604a-d, (ii) the Massive Channel Emulator (MCHEM) 303, (iii) the Traffic Generator (TGEN) 601, (iv) the GPU nodes 605, and (v) the management infrastructure 603. Diagram 620 of FIG. 6B shows that additional processing hardware 610 may be added for processes using AI/ML. The SRNs 604a-d, comprise several computer servers equipped with CPUs and GPUs to support heavy computation loads. Users of Colosseum reserve SRNs through a Graphical User Interface (GUI). The environments emulated by Colosseum are called RF scenarios, and are emulated on the MCHEM 303. The MCHEM 303 is formed of several FPGAs 606 and are distributed across the four quadrants of Colosseum. Signals generated by the SRN USRPs are sent to the corresponding USRP on the MCHEM 303 side. From there, they are converted in baseband and to the digital domain, and processed by the FIR filters of the MCHEM FPGAs that apply the CIR corresponding to the RF scenario chosen by the user of the testbed.

FIG. 6C shows diagram 630 illustrating the scenario conductor server that is streamed to the MCHEM 303 at execution time. The MCHEM 303 is formed of 16 FPGAs distributed across four quadrants Colosseum. Each Advanced Telecommunications Computing Architecture (ATCA) module include four FPGAs 611 that process through FIR filters 612a-c the signals from/to an array of USRP 613a-c (32 USRP per MCHEM quadrant, for a total of 128 USRP across the four quadrants of Colosseum) connected one-to-one, through Sub-miniature Version A (SMA) cables, to the USRP 614a-c driven by the SRNs 604a-c controlled by the users.

Instead of being transmitted over the air, signal generated by the SRN USRP 614a-c are sent to the corresponding USRP 613a-c on the MCHEM 303 side. From there, they are converted in baseband into the digital domain, and processed by the at FIR 612a-c filters of the MCHEM 303 FPGAs 611 that apply the CIR corresponding to the RF scenario chosen by the user of the testbed.

By enabling the dynamic digital twin scenario updated runtime, Colosseum as the digital twin is extended to allow end-users to update scenarios at runtime by introducing dynamic modification in their channel taps. This is realized through novel APIs that may be able to introduce variations in channel taps loaded by the scenario conductor server and streamed to the MCHEM at execution time. This introduces variability in the emulation process, as well as statistical relevancy to user experiments. These APIs are integrated with the GPU-based Ray-tracing allowing users to modify fixed scenarios with channel taps computed on-the-fly through the introduced GPU ray tracer. The APIs initially focus on the RF component of the digital twin emulations, and they are further executed to allow users to dynamically change configurations of the centralized unit (CU), distributed unit (DU), and radio unit (RU) as well as (for example, frequency, bandwidth, allocated resources, cell configuration, etc.).

Still referring to FIG. 6C, the FIR filters 612a-c comprise 512 complex valued taps that are set to reproduce conditions and characteristics of wireless channels in real-world environments, i.e., the CIR among each pair of SRN 604a-c. As an example, signal x generated by one of the SRNs (604a-c) is received by the USRP 613a-c of MCHEM 303 and transmitted to its FPGAs 611. Here, the FIR filters 612a-c load the vector h_{i,j} corresponding to the 512-tap CIR between nodes i and j (with i, j∈{1, . . . , N}set of SRNs active in the user experiment) from the RF scenario server, which contains a catalog of the scenario available on Colosseum. Then, taps are applied to xᵢ through a convolution approach. The signal yⱼ=Σᵢ₌₁^{N}xᵢ*h_{i,j} resulting from this operation, i.e., the originally transmitted x; signal with the CIR of the emulated channel, is finally sent to SRN j. Analogous operations also allow Colosseum to perform superimposition of signals from different transmitters, and to consider interfering signals (besides the intended ones), as it would happen in a real-world wireless environment. In this way, Colosseum can emulate effects typical of real and diverse wireless environments, including fading, multi-path and path loss, in terrains up to 1 square kilometer (km²) of emulated area, and with up to 80 megahertz (MHz) bandwidth, and can support the simultaneous emulation of different scenarios from multiple users. Furthermore, Colosseum is capable of emulating node mobility discretely. Every millisecond, the RF Scenario Server loads different pre-defined channel taps into the Colosseum FPGAs, effectively mimicking changes in channel conditions resulting from node position changes.

Similarly to the emulation of RF environments, the TGEN 601 allows users of the testbed to emulate different internet protocol (IP) traffic flows among the reserved nodes. This tool, which is based on the U.S. Naval Research Laboratory's Multi-Generator (MGEN) enables the creation of flows with specific packet arrival distributions, packet size, and rate. These traffic flows, namely traffic scenarios, are sent to the SRNs of the user experiment that, then, handles them through the specific protocol stack instantiated on the SRNs (e.g., Wi-Fi, cellular, etc.).

GPU nodes 605 (FIG. 6A) within Colosseum can stream data in real-time from/to the SRNs 604a-c through high-speed links and have the capability of powering computational-intensive workloads, such as those typical of artificial intelligence or machine learning applications.

In addition, Colosseum includes a management infrastructure 603 not accessible by the user that is used to maintain the rest of the system operational. A non-limiting list of services offered by the management infrastructure 603 include (i) servers that run the website used to reserve resources on the testbed, (ii) resource managers to schedule and assign SRNs and GPU nodes to users, (iii) multiple Network Attached Storage (NAS) systems to store experiment data and container images, (iv) gateways and firewalls to enable user access and isolation throughout experiments, and (v) precise timing servers and components to synchronize the SRNs, the GPU nodes, and the SDRs.

### Arena

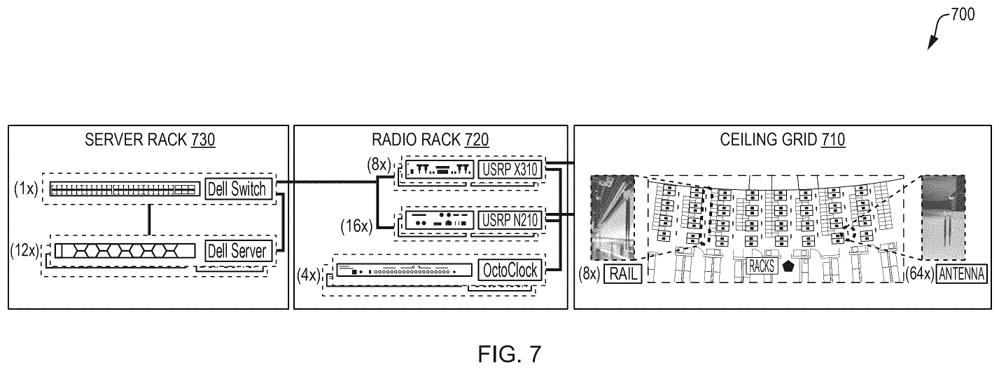

Arena is an over-the-air wireless testbed deployed on the ceiling of a real-world indoor laboratory space for experimentation. The architecture of Arena is depicted at a high level in diagram 700 of FIG. 7. Arena's main building blocks are (i) the ceiling grid 710, (ii) the radio rack 720, and (iii) the server rack 730.

For example, the ceiling grid 710 may concern 64 omnidirectional antennae in, for example, a 2450 square-foot (ft²) indoor office space. These may be deployed and arranged in 8×8 configuration to support multiple input/multiple output (MIMO) applications. The antennae of the ceiling grid may be cabled together. Softwarized protocol stacks (e.g., cellular, Wi-Fi, etc.) may be deployed on the computer nodes of the server rack 730, and connected through a programmable switch.

The process of digitizing real-world environments into the digital twin representation is composed of different steps: (i) RF scenario twinning, in which the physical environment is represented into a virtual scenario and validated thereafter; and (ii) protocol stack twinning, in which softwarized protocol stacks are swiftly transferred from the real-world to the digital twin, thus allowing users to evaluate their performance in the designed virtual scenarios.

The RF scenario twinning operations are performed by CaST described above. CaST allows users to characterize a physical real-world radiofrequency environment and to convert it into a digital representation, to be used in a digital plane, such as the Colosseum wireless network emulator. CaST is based on an open SDR-based implementation that enables (i) the creation of virtual scenarios from physical terrains, and (ii) their validation through channel sounding operations to ensure that the characteristics of the designed radiofrequency scenarios closely mirror the behavior of the real-world wireless environment.

The scenario creation framework includes several steps described above in relation to FIG. 4. CaST captures the characteristics of a real-world propagation environment and model it into a radiofrequency emulation scenario to install on Colosseum. These steps concern (i) identifying 401 the wireless environment to emulate; (ii) obtaining 402 a 3D model of the environment; (iii) loading 403 the 3D model into a ray-tracing software; (iv) modifying nodes and defining their trajectories 404; (v) sampling the channels 405 between each pair of nodes; (vi) parsing 406 the ray-tracing output of the channel samples; (vii) approximating 407 the obtained channels in a format suitable for the emulation platform (e.g., Colosseum MCHEM FPGAs); and (viii) installing 408 the scenario on Colosseum.

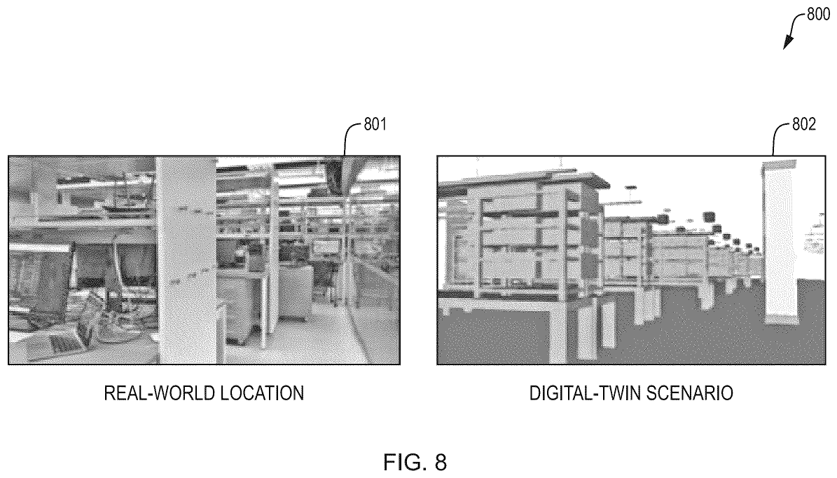

FIG. 8 shows an example representation 800 illustrating a real-world environment 801 and the 3D model 802 of the real-world environment 801 after the 3D model has been obtained for the environment and the environment has been loaded into a ray-tracing software. In this example, SketchUp was used as the software to create the 3D representation of the Arena test bed. Any software that allows for users to model broad range of environments starting from an architectural layout with different surface renderings may be appropriate. The resulting 3D model is then fed into the ray-tracing software, in this and for example, Wireless InSight (WI), to create a digital twin scenario on Colosseum.

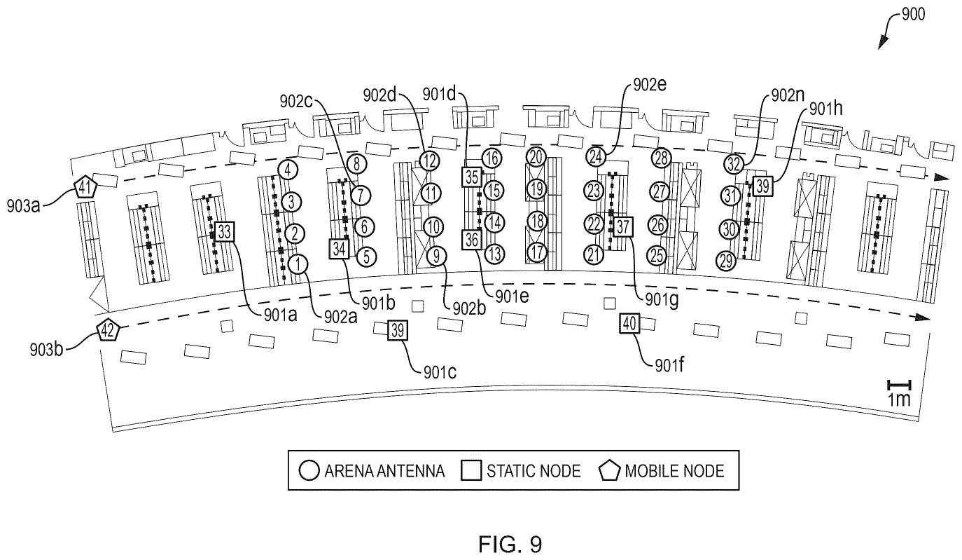

FIG. 9 shows a representation 900 the modeled antenna points 901a-n (not all antenna are labeled for clarity) of the Arena test bed (from FIG. 8) in 32 locations (one for each antenna pair) as well as eight static nodes 902a-h distributed in their surroundings, and two mobile nodes 903a-b traversing the laboratory space at a constant speed of 1.2 meters per second. The height of the nodes is set to Im, to emulate handheld devices, or devices laying on table surfaces.

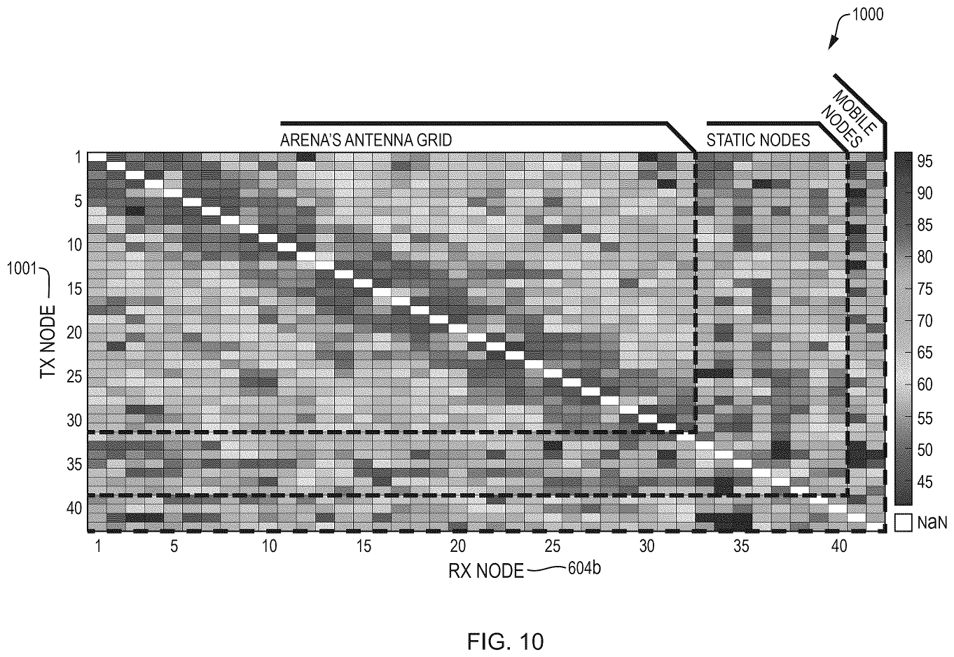

FIG. 10 shows a heat map 1000 illustrating the path loss amongst the transmitter 1001 and receiver 1002 node pairs. As expected, closer nodes experience a lower path loss, which increases the distance between the nodes. A similar trend is also visible for the static nodes, even though this is less noticeable due to their scattered locations. On the other hand, due to the remote starting locations on the side of the room, the mobile nodes exhibit a very high path loss against all nodes. These path losses decrease as they get closer to each node on their pair, and increase again while reaching their end locations on the other side of the room.

### Testing Validation

The following sections disclose validation and testing for embodiments disclosed herein. The first section presents an example test relating to cellular networking, in order to confirm the capabilities of DigiRAN to perform emulated cellular experiments that closely replicate the behavior of real-world setups and environments, even in the presence of mobile nodes. The second section presents an example test relating to Wi-Fi jamming, in order to prove the ability of DigiRAN to properly emulate various use case experiments with different protocol stacks and scenarios. The third section relates to mobility in RF scenarios, detailing DigiRAN's capabilities of replicating accurate networks with moving components. The next section describes the validation for CaST by finding a code sequence that can result in high autocorrelation and a low cross correlation between transmitted code sequence and received signal, as well as using CaST to understand the behavior of Colosseum emulation by testing a set of synthetic scenarios, such as the above referenced mobility scenario. The final test results section demonstrates the effectiveness of DigiRAN as a detector in identifying radar signals and vacating the cellular bandwidth.

### Cellular Networking

This section shows outcomes of relevant experimental use cases run on the Arena test bed, as well on its digital twin representation.

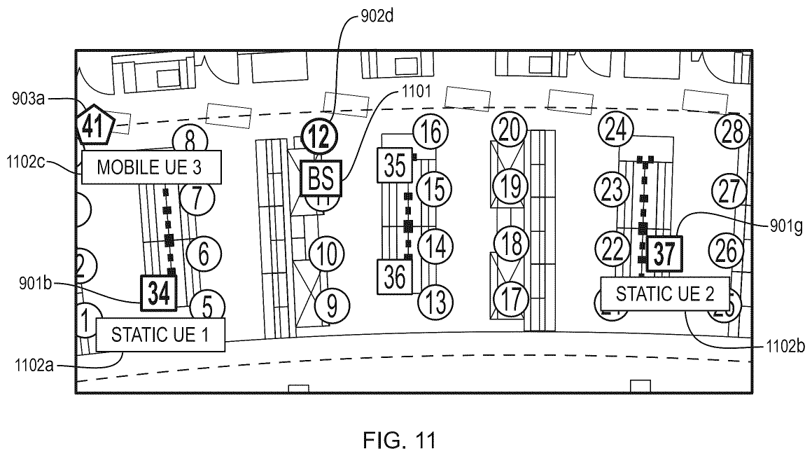

FIG. 11 shows an enlarged section 1100 from FIG. 9, illustrating a cellular networking use case, where an open source framework is leveraged for experimentation of cellular networking technologies to deploy a twinned radio access network protocol stack with one base station (BS) 1101 and three user equipment (UEs) 1102a-c in the Arena over the air test bed and in the Colosseum emulation system. The same node positions are used in the two platforms. The base station 1101 which transmits over a 10 MHz spectrum, is located on node 12 (902d), two static UE on nodes 34 (901b) and 37 (901g) and one mobile UE on node 41 (903a). In the Arena case, UEs are implemented through commercial smartphones. While on Colosseum, they are deployed on the SDRs of the test bed. Two experiments were conducted on each system: the first one involves a downlink user datagram protocol traffic sent at 5 megabits per second (Mbps) rate; the second one Transmission Control Protocol (TCP) downlink traffic. The traffic generation for each experiment is achieved using a benchmarking tool designed for assessing the performance of IP networks. The following results show the average of at least five separate experimental realizations.

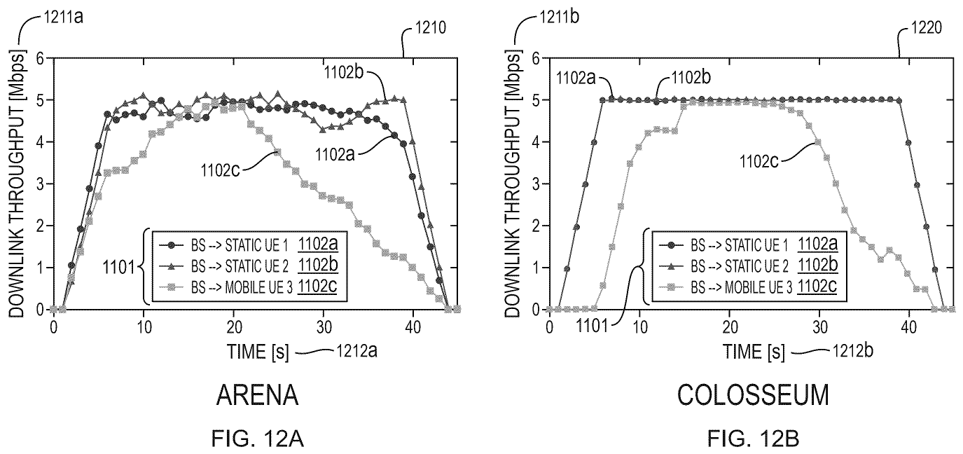

FIGS. 12A and 12B shows plots 1210 and 1220 respectively illustrating the User Datagram Protocol (UDP) downlink throughput for static and mobile nodes on the Arena (1210 FIG. 12A) and Colosseum (1220 FIG. 12B) test beds. Both plots 1210 and 1220 represent Downlink Throughput (Mbps) 1211a-b over time in seconds (s) 1212a-b for the BS 1101 to UEs 1-3 (1102a-c respectively). A similar trend and pattern can be seen exhibited on both test beds. Specifically, the throughput of the static nodes remains stable around 5 Mbps in both Colosseum and arena, where we notice a less stable behavior due to the use of over the air communications, and potential external interference. The throughput of the mobile node increases as the node gets closer to the base station and then decreases as the node get further away.

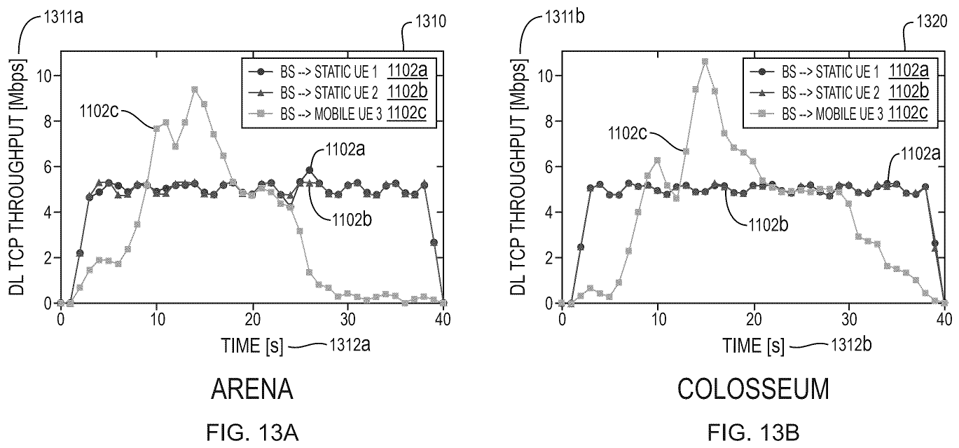

FIGS. 13A and 13B show plots 1310 and 1320 respectively illustrating TCP downlink throughput 1311a-b versus time 1312a-b for the BS 1101 to UEs 1-3 (1102a-c respectively) of the cellular use case on the Arena (1310 FIG. 13A) and Colosseum (1320 FIG. 13B) testbeds.

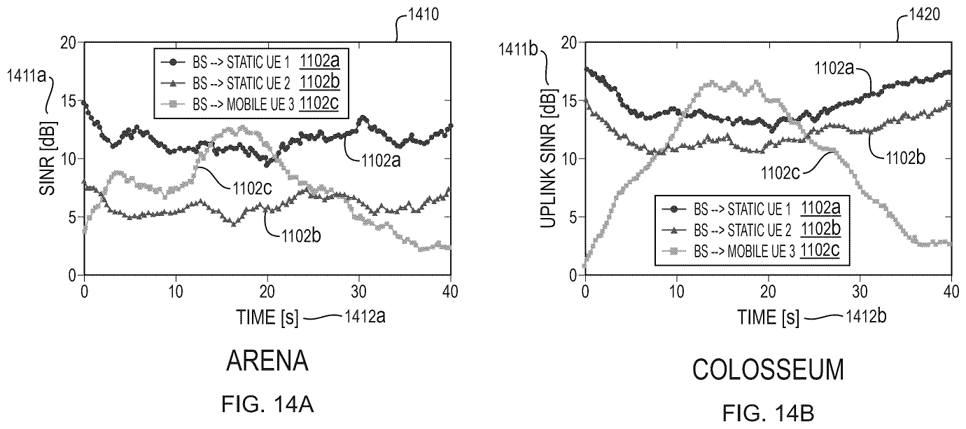

FIGS. 14A and 14B show plots 1410 and 1420 respectively illustrating Signal to Interference-plus Noise Ratio (SINR) 1411a-b in dB versus time 1412a-b for the BS 1101 to UEs 1-3 (1102a-c respectively) of the cellular use case on Arena (1310 FIG. 13A) and Colosseum (1320 FIG. 13B) testbeds.

FIGS. 13A through 13B and 14A through 14B plot the TPC downlink throughput and SINR results of the second experiment for static and mobile nodes on Arena and Colosseum. Also in this use case, a similar pattern is clearly noticeable. In particular, the two static nodes UE 1 1102a and UE 2 1102b maintained a relatively stable throughput of the nominal 5 Mbps TCP traffic on both test beds with no apparent impact during the passage of the mobile UE 3 1102c close to the static UEs (UE1 1102a and UE 2 1102b), which in the Arena case is moved manually. This behavior is visible in the SINR results, which show a decrease due to the created interference when the mobile node (UE 3 1102c) approaches each of the static UEs. The mobile node (UE 3 1102c) exhibits a similar trend with two high peaks in throughput on both systems. These peaks can be attributed to the TCP protocol, which retransmits data to ensure delivery in case of packet failures as soon as the signal improves, resulting in higher application throughput values compared to the nominal 5 Mbps. Specifically, each peak corresponds to the time right after the mobile device transitions close to static node 1 (UE 1 1102a) (around time 10 seconds), and then to static node 2 (UE 2 1102b) (around time 15 seconds). Due to the increased interference, the mobile node (UE 3 1102c) lose more packets, which are eventually retransmitted.

By analyzing the results after the UEs have completed the attachment procedures, the cross correlation can be calculated to assess the similarity between the two test beds. Table 1 below presents the normalized cross correlation results and their averages for each UE, considering the maximum values between 10 lags, and both throughput and SINR for the UDP and TCP use case experiments.

TABLE 1

| Metric | Static UE: 1 | Static UE: 2 | Mobile UE: 3 | Average |
|---|---|---|---|---|
| UDP Throughput | 0.986 | 0.998 | 0.999 | 0.994 |
| TCP Throughput | 0.937 | 0.998 | 0.998 | 0.978 |
| TCP SINR | 0.997 | 0.994 | 0.982 | 0.991 |

What can be observed is a very high similarity between the two test beds in all use case experiments, with individual UE values consistently above 0.93 and an average exceeding 0.97 for each use case metric. As can be shown in FIGS. 14A and 14B, the SINR results in Arena are quite similar from UE 1 1102a and UE 3 1102c and they present a fixed difference of about 5 decibels compared to colosseum for UE 2 1102b. This difference can mainly be attributed to the additional and uncontrolled interference and impairments of a real-world radio frequency environment, as well as the different power levels between a simulated UE and a real smartphone. However, these variances can be compensated for in the digital twin by adjusting factors such as the node gains at the transmitter like receiver, as well as by adding stochastically representative interference models to the channel that represents the real-world behavior more closely. These findings confirm the capabilities of the digital twin to perform emulated cellular experiments that closely replicate the behavior of real-world setups and environments, even in the presence of mobile nodes.

### Wi-Fi Jamming

Adversarial jamming has continuously plagued the wireless spectrum over the years with the ability to disrupt, or fully halt, communications between parties. While there are potential solutions to specific types of jamming, due to the open nature wireless communication, this kind of attack continues to find ways to be effective. However, the development of new techniques to counter this attack is not always straightforward, even experimenting with possible solutions requires complying with strict FCC regulations. Even though some environments allow for jamming research, these setups can hardly capture the characteristics and scale of real-world network deployments. To bridge this gap, a digital twining environment, provided by DigiRAN embodiments presented herein, may be fundamental in further developing techniques for jamming mitigation.

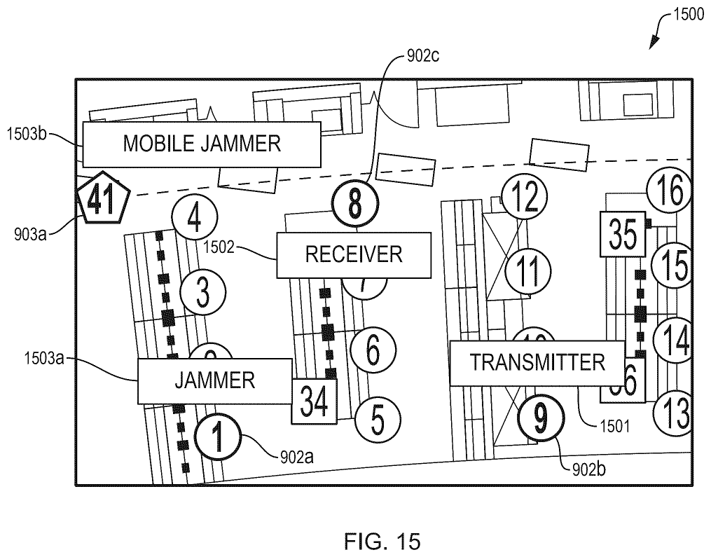

FIG. 15 shows a close-up view 1500 of the Arena environment from FIG. 9 illustrating, within Arena, the nodes in the jamming equipment comprising of three static nodes 902a-c and one mobile node 903a. The GNU radio-based implementation is leveraged to deploy two Wi-Fi nodes (a transmitter 1501 and a receiver 1502) communicating over a 20 megahertz spectrum on the Arena testbed. Additionally, GNU Radio is leveraged to deploy a jammer on both stationary 1503a and mobile 1503b nodes that transmits Gaussian noise signals to hamper the correct functioning of our Wi-Fi network. For the sake of fairness in the transmitted signals, and the stationary case, the nodes were deployed such that the Wi-Fi transmitter and jammer are at the same distance from the Wi-Fi receiver.

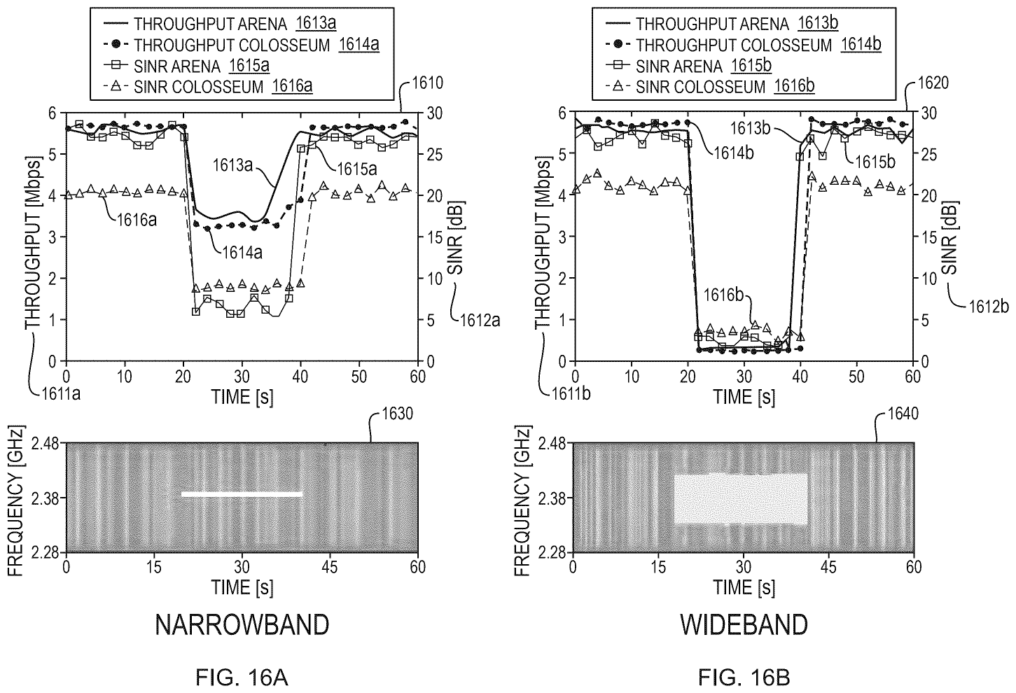

FIGS. 16A and 16B show plots 1610, 1620, 1630 and 1640 illustrating the two common forms of static jamming that were considered: jamming through narrow band signals (1610) and jamming through wide band signals (1620). These plots 1610 and 1620 show the throughput 1611a-b and SINR 1612a-b for both Arena and Colosseum. Arena throughput is shown by lines 1613a-b, Colosseum throughput is shown by lines 1614a-b, Arena SINR is shown by lines 1615a-b and Colosseum SINR is shown by lines 1616a-b. The first type of jamming only occupies a small portion of the Wi-Fi bandwidth (about 156 kHz), resulting in a minimal displacement of the Wi-Fi signals. On the contrary, the latter covers half of the spectrum used by the Wi-Fi nodes (for example 10 megahertz), causing larger disruptions in the network. FIGS. 16A and 16B evaluate how narrowband and wideband stationary jammers impact the throughput and SINR of the Wi-Fi network in the real and digital twin-based scenarios, respectively. The Wi-Fi nodes communicate for 60 seconds, and the jammer starts transmitting at second 20 for duration of 20 seconds. Specifically, FIG. 16A shows the Wi-Fi throughput 1611a and SINR 1612a for the narrowband jamming experiment in both the real-world and the digital twin, while the wideband jamming experiment throughput 1611b and SINR 1612b results as perceived by the Wi-Fi nodes are shown in FIG. 16B.

By looking at the narrowband jamming case (FIG. 16A), it can be seen that in the real-world experiment the Wi-Fi throughput (1611a) achieves between 5 and 6 Mbit/s when there is no jammer. Once the jammer starts (at second 20) a rapid decrease in the throughput (between 37% and 43% decrease) can be seen. The wide band jammer (FIG. 16B) instead, has more severe impact on the Wi-Fi throughput, causing a performance drop between 94% and 96% (with the throughput achieving values between 220 and 290 kbit/s). In both narrowband and wideband cases, the behavior obtained in the digital twin is consistent with that of the real-world scenario. Analogous trends can be seen for the SINR of both signal types, where the narrow band jammer causes a SINR decrease of approximately 20 decibels (about 77% decrease), while the wide band jammer of approximately 25 decibels (about 92% decrease) in the real-world scenario. Similar to the previous case, results are consistent with those of the digital twin.

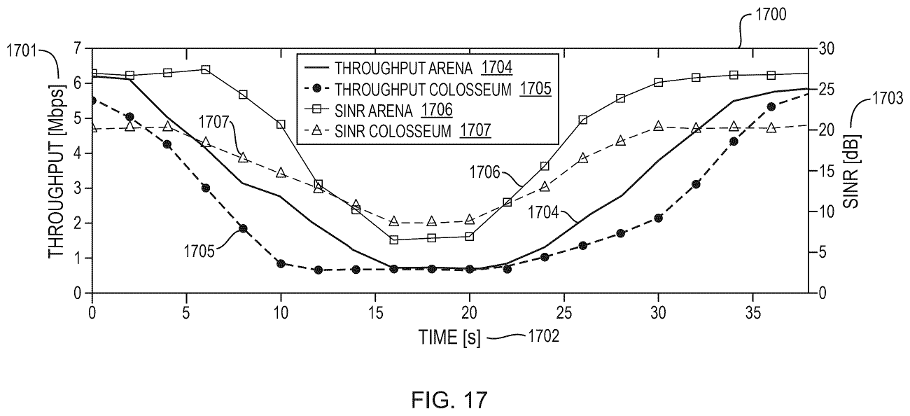

FIG. 17 shows plot 1700 that illustrates the impact that a mobile jammer has as it's moving at pedestrian speed on the Wi-Fi throughput. Wi-Fi nodes are located as in the previous case, i.e., the receiver node 1502 and the transmitter node 1501 of FIG. 15. Arena throughput is shown by line 1704, Colosseum throughout is shown by line 1705, Arena SINR is shown by line 1706, and Colosseum SINR is shown by line 1707. As expected, the impact of the jamming signal on the Wi-Fi throughput 1701 varies as the jammer moves closer and further (over time 1702) from the Wi-Fi receiver. Specifically as the jammer gets closer to the Wi-Fi nodes (seconds 5 to 30), we observe about a 90% decrease in throughput in both the real-world and the digital twin scenarios. A similar decrease can be observed in the SINR 1703 as well, where we notice a clear drop in both the over the air arena case and the digital twin following a look alike trend.

Table 2 below illustrates the normalized cross correlation results, and their averages, considering the maximum values between 10 lags for each jamming experiment.

TABLE 2

| Metric | Narrowband | Wideband | Average |
|---|---|---|---|
| Static Throughput | 0.996 | 0.382 | 0.989 |
| Static SINR | 0.986 | 0.984 | 0.985 |
| Mobile Throughput | 0.982 | — | — |
| Mobile SINR | 0.993 | — | — |

A strong similarity can be observed between the two test beds in both static and mobile experiments, with individual values consistently above 0.98. Overall, considering the simple experiments the digital twinning platform is able to achieve an average similarity of 0.986 in throughput and 0.989 in SINR. These results prove the ability of this system to properly emulate various use case experiments with different protocol stacks and scenarios.

### Mobility in RF Scenarios

For an example vehicle to everything scenario taking place in Tampa FL, a use case is provided below. A scenario is considered around the Tampa Hillsborough Expressway in Tampa FL. In order to simulate the wireless scenario in WI, a 3D model is needed of the wireless environment. The 3D model is obtained using open street map and an XML format file and converted into an STL file, which is supported by WI.

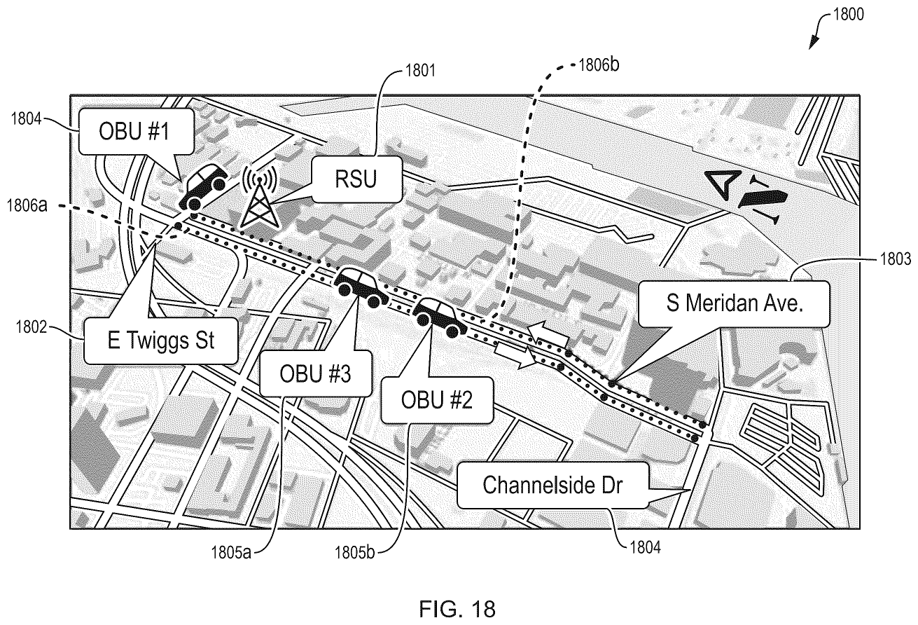

FIG. 18 illustrates an example scenario 1800 where a V2X model is considered with four nodes. One is a roadside unit (RSU) 1801 mounted on the traffic light at the intersection of E. Twiggs St. 102 and N. Meridian Ave. 1803. The other three nodes are Onboard Units (OU) installed on three vehicles: one is stationary 1804 and parked in the parking lot of the Tampa Expressway authority; and the other two vehicles 1805a-b are following each other at a constant speed of 25 mph on Meridian Ave. 1803 from east Twiggs St. 1802 to Channelside Drive 1804, and then back to east Twiggs St. 1802. The radio parameters of the nodes are listed in Table 3 below.

TABLE 3

| Parameters | Values for V2X |
|---|---|
| Carrier Frequency | 5.915 [GHz] |
| Signal Bandwidth | 20 [MHZ] |
| Transmit Power | 20 [dBm] |
| Antenna Pattern | Omnidirectional |
| Antenna Gain | 5 [dBi] |
| Antenna Height | RSU: 16 [ft], OBUs: 5 [ft] |
| Ambient Noise Density | −172.8 [dBm/Hz] |

The effect of mobility is captured by sampling the channels with a predefined sampling time interval of T_{S} while the transmitter or receivers are moving. This channel sampling concept can be implied in the ray-tracing simulation by spatially sampling the trajectory of the mobile nodes in the scenario with the spacing of Dᵢ=Vᵢ*Tₛ where Vᵢ is the velocity of the i^{th} mobile node.

For mobility simulation, it is important to consider spatial consistency, which means that the mobile nodes may experience a similar scattering environment with smooth channel transitions due to the motion. The spatial consistency does not deal with the small-scale correlation of received power levels, but rather focuses on providing a constant and correlated scattering environment that a mobile node experiences. The coherence distance of five meters recommended in 3GPP, which inherently assures the spatial consistency since ray-tracing is used for the physical environment to simulate spatial and time evolution, so that the generated parameters of those two close locations are highly correlated.

The spatial sampling concept can be implemented in WI using the “route” or “trajectory” type for transmitters and receivers, where the user can define the trajectory of the mobile nodes in the WI GUI. This trajectory is defined by determining some control points to specify the start, the end, and where the movement direction is changed. Then, WI fills in the trajectory with receiver points and the user can set the spacing between these points. To mimic the channel sampling in real-world, the spacing is set with the values calculated as D=V*Tₛ, where Tₛ is constant for all the mobile nodes, hence the spatial sampling of each node is determined by its velocity. In this use case scenario, V=25 mph for mobile vehicles and the sampling interval time is set to 447 ms, hence D=5 m which guarantees the spatial consistency. Given the total length of the path about two kilometers, WI generates Ns'₂ 391 samples along the trajectory shown by the dotted lines 1706a-b in FIG. 17.

In the next step, the shield samples and the valid channels per time are parsed from the ray-tracing outputs to extract synchronized channels between the sample of mobile and other stationary nodes. WI runs the ray-tracing process for a total number of channels between each pair of transceivers N_{ch}=(N_{nodes})², and stores the results at each timestamp, i.e., a total of Nₛ*N_{ch} channel realizations.

WI stores the ray-tracing output of each individual transmitter in a separate file which represents the channels between the individual transmitter and all the receivers in the scenario. Algorithm 1 below shows the parsing of the channel outputs between each pair of nodes all time stamps for the entire duration of a scenario Tₜₒₜₐₗ.

ALGORITHM 1: Mobility Simulator Algorithm

| | |
|---|---|
| 1 | $Number of samples , {N}_{s} = \frac{{T}_{total}^{- 1}}{{T}_{s}} + 1$ |
| 2 | channel = struct (gain, ToA, AoAs, AoDs) |
| 3 | Channel matrix CH: 3D matrix (N_{node}, N_{node}, Nₛ) of |
| | channel |
| 4 | time = time evolution of simulation |
| 5 | for sample s = 1 to Nₛ do |
| 6 | for each TX, I, do |
| 7 | for each RX, j, do |
| 8 | if Vᵢ = 0 & s > 1 then |
| 9 | CH(i, j, s)=CH(i, j, 1) |
| 10 | continue |
| 11 | find TX(i) sample, x = min(s, max TX(i)) |
| 12 | [symbol] Read ray-tracing output file TX(i) for x |
| 13 | find RX(j) sample, y = min(s, max RX(j)) |
| 14 | [symbol] channel = Extract channel RX(j) for y |
| 15 | CH (i, j, s) = channel |
| 16 | time(s) = (s-1) × Tₛ |
| | Output: time, CH |

The output of the CaST mobility simulator is a 3D matrix structure that includes NS 2D matrix pages. Each page stores the channels between the transmitters in rows and receivers in columns.

For time variant multipath parameters, the temporal characteristics of the wireless channel are considered, as an FIR filter, where the CIR varies in time and can be expressed by Equation (7) below. Nₜ Is the number of paths at a time t, cᵢ is the i^{th} path gain coefficient, and τᵢ is the ToA of the i^{th} path, which both vary in time period further, the path gain coefficient is a complex number which carries the magnitude, aᵢ and the phase shift φᵢ of the i^{th} path shown in Equation (8) below.

$$h ( t , r ) = {\sum }_{i = 1}^{{N}_{t}} \tilde{c} ( t ) \cdot δ ( t - {τ}_{i} ( t ) ) \qquad ( 7 )$$

$$\tilde{c} ( t ) = {a}_{i} ( t ) \cdot {e}^{j {φ}_{i} ( t )} \qquad ( 8 )$$

The time variant CIR is obtained from the estimated parameters of channel paths for each of the valid channels sampled at time instance t from the ray tracer output. The tracer reports the paths between transmitters and receivers and calculates ToA, received power, and phase shift of the received signal, as well as the angular characteristics for each path. This process takes into account the path trajectory distance and the reflection coefficient of the materials at each reflection point. In WI, simulation output finds paths with power >−250 dBm, which include the ones below the noise floor. Then, the paths are pruned with received power lower than the noise floor. This is computed using Equation (8) below, where Nₒ, B and F are the ambient noise density [dBm, Hz], the receiver bandwidth [Hz], and the receiver noise figure [dB] respectively

$$Noise [ dBm ] = {N}_{o} + 10 * log B + F \qquad ( 8 )$$

However, WI did not directly report the gain parameter of the paths for the valid channels at the time instant t, so the gain of the paths is calculated as complex numbers using Equation (9) below, where P_{T}_{ₓ} is transmit power in dB and P_{R}_{ₓᵢ} and φᵢ are the received power and signal phase per each path i∈{1 . . . Nₜ}respectively.

$${\tilde{c}}_{i} ( t ) = {10}^{( {P}_{{R}_{{x}_{i}}} ( t ) - {P}_{{T}_{x}} ) / 20} * {e}^{{j}_{{φ}_{i}} ( t )} i = 1 … {N}_{t} \qquad ( 9 )$$

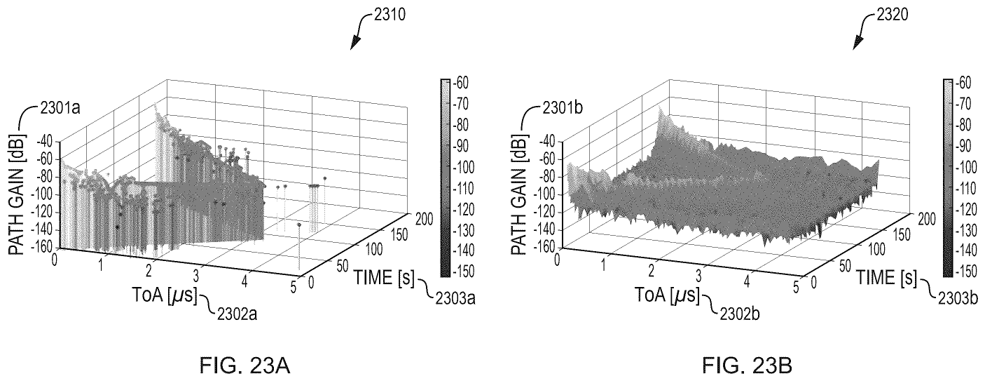

The use case scenario for the street in Tampa FL discussed above is simulated in WI by considering four reflections to find the path this is between the transmitter and receivers for a reasonable simulation time period the time variant CIR of the RSU is computed to obtain OBU #3 channel 1705a, which is described below in relation to FIGS. 23A and 23B. As a final metric, the impact of mobility on path loss is evaluated, which is one of the important channel parameters for large scale channel characterization to recognize the fading impact of mobility and multi-paths. To this end, link path loss Lₚ is calculated using Equation (10) below which is the magnitude of coherently summation of the coefficients in dB.

$${L}_{p} ( t ) = - 20 log \vert {\sum }_{i = 1}^{{N}_{t}} \tilde{c} ( t ) \vert \qquad ( 10 )$$

Due to computational restrictions and trade-offs, FIR based channel emulators can only account for a limited number of nonzero filter taps (for example Colosseum only supports four taps). However, the ray tracer derived models typically include numerous paths between transmitters and receivers. Furthermore, delays of paths may not be necessarily aligned with the predefined stepwise delays of the emulator FIR filter taps. To this end, a tap approximation framework is used that employs machine learning based clustering methods to convert the ray tracer channels into the taps format compatible with the requirements or limitations of the channel emulator. This involves approximating the channels to an acceptable number of paths, aligning the tap delays to the predefined indices, and adjusting the dynamic range of the taps while preserving a desirable accuracy from the original channel.

### CaST Validation

CaST was run a laboratory test bed to tune the parameters in it controlled environment in the absence of channel emulator impairments. One of the main goals of this step is to find a code sequence that can result in high autocorrelation and a low cross correlation between transmitted code sequence and received signal, which consequently can reveal channel tabs. Secondly, CaST is used to understand the behavior of Colosseum emulation by testing a set of synthetic scenarios, created specifically for the sounding purpose. Finally, a quasi real-world scenario with static and mobile nodes (such as the mobility scenario described above) are deployed characterized.

A customized Linux container image containing CaST was created and uploaded to Colosseum. This container had all the required libraries and software for the channel sounding system and its process processing operations. This enabled the reusability of the sounding with different Colosseum SRN scenarios, and allowed for the automation of all processes until the generation of the final result.

Validation tests included two USRP x310 radios, each equipped with one daughter board. The radios were synchronized in time and frequency through a clock distributor which generated the clock internally. A computer was used to program the radios, and to perform the post-processing operations. The default connection between the two USRP includes cables and attenuators for a total of 30 decibels of attenuation. The sounding parameters for the lab experiment are summarized in Table 4 below. The gains of the USRP vary between 0 and 15 decibels to understand their effect. The code sequence is a Galois Linear Feedback Shift Register (GLFSR). The receiving period time and data acquisition were set to three seconds.

TABLE 4

| Parameter | Value |
|---|---|
| Center frequency | 1 GHz |
| Sample Rate | Various 1-50 MS/s |
| USRP tx gain | Various 0-15 dB |
| USRP rx gain | Various 0-15 dB |
| Code Sequence | GLFSR 255 bits |

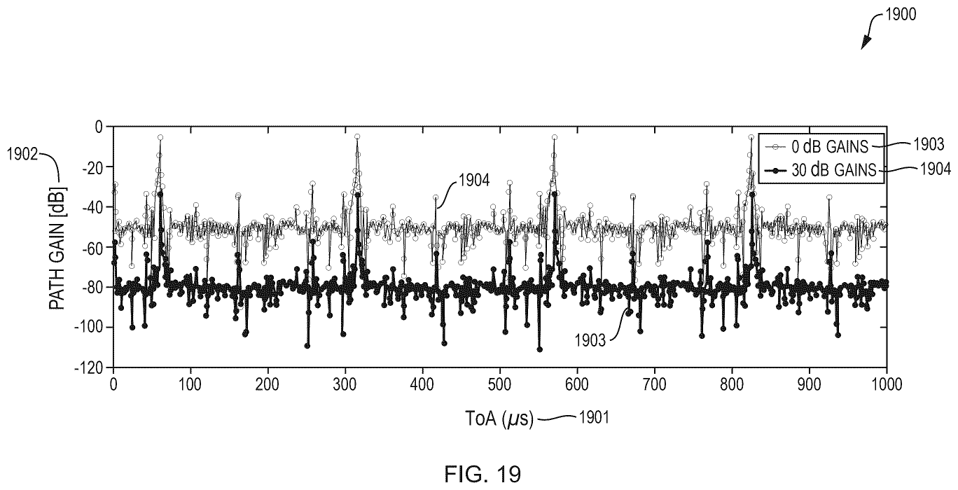

FIG. 19 shows a plot 1900 illustrating a time frame (ToA 1901) of the received path gains 1902 for a case with 0 dB gains 1903 and 30 dB gains 1904, consisting of 15 dB on the transmitter and 15 dB on the receiver.

The signal cycles based on the transmitted sequence length, i.e., every 255 sample points, or equivalently, every 255 μs since one point is equal to 1/sample_rate=1 μs. The peak represents the path loss of the signal tap of this laboratory validation experiment and it's equal to 34.06 dB for the 0 dB case and 5.24 dB for the 15 dB. These numbers are in line with the expectation since we have 30 decibels lost due to attenuators and a few more due to the radios, cable, attenuators, computational and precision, and some background noise. Moreover, it can be seen that in the 30 dB case, the loss is slightly more since there USRP might not add 30 dB total but slightly less.

Code sequences have been widely investigated in literature given their high utility in many different fields. Good code sequences target a high autocorrelation, i.e., correlation between two different sequences. By exploiting the lab testbed environment described above, four code sequences were tested to find out the one with the CIR that best fits these experiments.

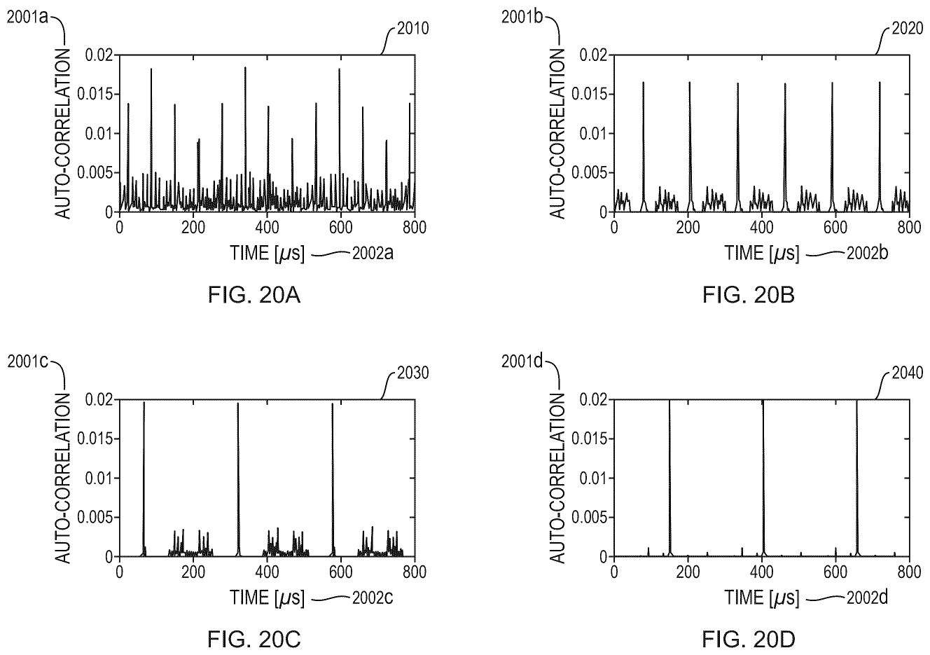

FIGS. 20A through 20D shows plots 2010, 2020, 2030, and 2040, respectively, illustrating four different code sequences auto-correlation 2001a-d against time 2002a-d, respectively, illustrating a time frame CIR for each code sequence. FIG. 20A shows plot 2010 illustrating the “Gold Sequence” having 255 bits created with the MATLAB Gold sequence generator system object with its default parameters. FIG. 20B shows plot 2020 illustrating the “Galaxy Sequence” Type A (Ga₁₂₈) with a size of 128 bits. FIG. 20C shows plot 2030 illustrating the “Loosely Synchronized” (LS) Code generated via exploiting the first codset of {1, −1} without including the Interference Free Window. FIG. 20D shows plot 2040 illustrating the GLFSR of 255 bits created via the GNU Radio GLFSR Source pseudo-random generation block with a degree of shift register being 8, the bit mask being 0, and the seed being 1. It can be seen in FIG. 20, the GLFSR sequence (2040) outperforms the other three having the highest autocorrelation, and lower cross correlations compared to the other ones resulting in a cleaner CIR.

The first set of scenarios are synthetic, i.e., manually generated with specific characteristics to validate MCHEM behavior. The set of use parameters is the same as Table 4 above, but with a sample rate of 50 MS/s to have enough resolution (20 ns per sample) to properly retrieve tap delays and gains.

The first tested scenario is the simplest one single tap with nominal 0 dB path loss period the results show the signal properly cycles every 5.1 μs with a recurrent average loss around 58 dB. This loss can be traced back to Colosseum equipment in the loop, having four USRP x310 radios and several cables, and emulation computation approximations. This number can be referred to as Colosseum based loss.

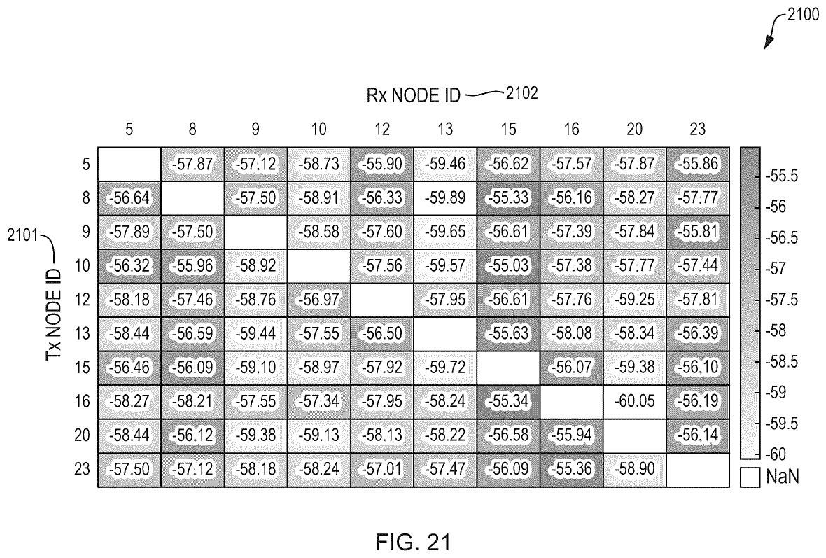

FIG. 21 shows a path loss heat map 2100 in a 0 dB scenario with 10 nodes. Each cell represents the average path loss for two seconds reception time between the transmitter node 2101 and the receiver node 2102 using both the first daughterboard. Results confirm an average Colosseum base loss of 57.55 dB with a standard deviation of 1.23 dB. It is also observed that the current dynamic range of Colosseum operations is about 43 dB, i.e., between the maximum value at 0 dB scenario of 57.55 dB and the minimum one, given by the noise floor at 100 dB. These are fundamental findings that need to be considered when designing scenarios and analyzing results.

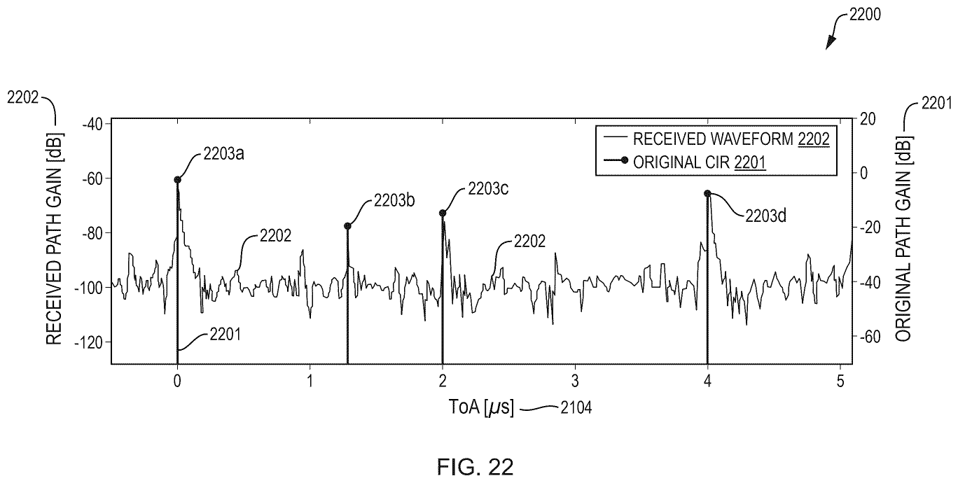

FIG. 22 shows a plot 2200 illustrating the next synthetic scenario analyzed included four taps with different delay times and path gains 2203a-d. The resulting received gains 2202 show that the ToA 2204 of the different taps are exactly the same, namely [0-1.25-2-4] μs. The received powers are in line with the expectations. If the base loss from Colosseum is added, the gain results match the original ones, particularly [3-20-15-8] dB losses. By considering a large number of frame times, for example, 15 hundreds, we can calculate the relevant differences of the received tap gains over time to obtain information on the accuracy of these measurements.

The average difference between the highest first taps of each time frame is in the order of 10⁻⁶ with a standard deviation of 0.03 dB. The same average happens for the lowest second taps with a slightly higher standard deviation of 0.17 dB. On the other hand, considering the differences between the highest and the lowest taps for each time frame, there is an average difference of 0.52 dB with a standard deviation of 0.18 dB. These results are a consequence of the contribution of the noise, which is largest in the lowest taps compared to the highest ones. These results prove that MCHEM and is emulating the channel correctly for both delay and gain taps, and that the received expected signal is consistent with the original one. Moreover, this shows that CaST is able to achieve a resolution of 20 ns, sustaining the sample rate of 50 MS/s and an accuracy on the tap gains measurement of 0.5 dB.

With reference to the mobility scenario described above, the mobility scenario has also been installed in colosseum with an increase of 60 dB in all taps, to fall inside the Colosseum dynamic range. These parameters for the sounding process are the same as those listed in table 4 above with 15 dB gains and 10 MS/s sample rate period since the total scenario time is 175 s and processing all the data together would require extreme memory, the reaction time is divided into 3 chunks of around 60 seconds each. In this way, each chunk is around 5 gigabytes in size and it takes about 30 minutes to be processed. The results of each chunk are cleaned and merged together to create the ultimate outcome. The received path gains have been adjusted by removing the Colosseum base loss and adding the original 60 dB increase.

FIGS. 23A and 23B show plots 2310 and 2320, respectively, illustrating path gain 2301a-b, the ToA 2302a-b over time 2303a-b the original taps representation (2310) and the received path gains (2320). Plot 2320 shows how the received path gains vary over the scenario time. The strongest tap resembles the same “V shape” behavior seen in the original taps representation 2310 as a direct consequence of a movement to and from the static RSU node.

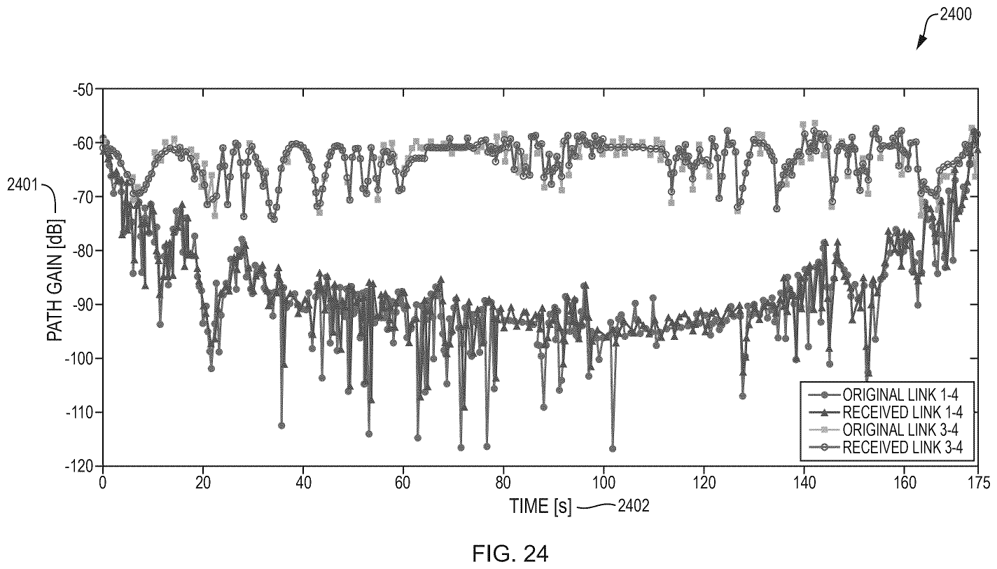

FIG. 24 shows plot 2400 illustrating a comparison between the original and received path gains 2401 over time 2402 for OBU #3 (See FIG. 17, 1705a) against RSU (See FIG. 17, 1701) and OBU #2 (See FIG. 17, 1705b). The overall original and received results are fluctuating due to the multipath fading, but they almost perfectly align between each other period in this case, for every link 1-4 a very similar received power trend with convex “U shape” close to the mobile node is first getting away from the RSU moving South decreasing the gains and increasing the ToA, then the pattern is reversed as the vehicle turns around and travels back toward the intersection and the RSU. On the other hand, link 3-4 has a more stable trend since the two vehicle nodes performed the journey together. These results confirm that Colosseum is emulating the channel correctly even a mobility scenario, and further validates the capabilities of CaST even when the metrics are changing over time.

### Radar Interference Use Case Proof

In this section the use case of 4G and 5G radio access networks transmitting in the Citizens Broadband Radio Service (CBRS) band are considered that need to vacate said bandwidth because of an incoming radar transmission. CBRS regulations allow commercial broadband access to the radio frequency spectrum rating from 3.55 GHz to 3.7 GHz, as depicted in the Code of Federal Regulations (CFR). This spectrum is shared with various incumbents, including the United States military, which operates radar systems in this frequency range, e.g., shipborne radars along the U.S. coasts. According to these regulations, dynamic access to the spectrum is permitted as long as the network is able to detect the presence of the radar and activates interference mitigation measures when necessary. Base Stations leverage artificial intelligence and machine learning agents to perform interference on the received IQ samples and detect incoming radar transmissions. Once detected, BSs either moved to an unused bandwidth, if any, or terminate any ongoing communication to give priority to the radar. To effectively study this use case in the Colosseum wireless network emulator, a radio frequency propagation environment was developed located on Waikiki Beach in Honolulu HI, in which a coastline BS working in the CBRS bandwidth needs to vacate said bandwidth due to the start of radar transmissions from a boat moving in the North Pacific Ocean.

Radar systems leverage reflections of radio frequency electromagnetic signals from a target to infer information on such target. Typical information may include detection, tracking, localization, recognition, and composition of the target, which include aircraft, ships, spacecraft, vehicles, astronomical bodies, animals, and weather phenomenon. Even though radar's uses were mainly related to military applications, this technology is commonly used in other areas, such as weather forecasting and automotive applications.

A weather radar is leveraged that combines techniques typical of continuous wave radars, e.g., pulse timing to compute the distance of the target, and of pulse radars, like the Doppler effect of the return signal to establish the velocity of the moving target. Similar considerations can be applied to any other radar waveform type, and the radar signal considered in this example is a use case study to showcase Colosseum capabilities. This radar operates in the S-band typically located within the [3.0, 3.8] GHz frequency range. The signal has been synthetically generated as a collection of IQ samples and timestamps, with a sampling rate of 6 MS/s and 106,657 sampling points for a total duration of 17.8 ms.

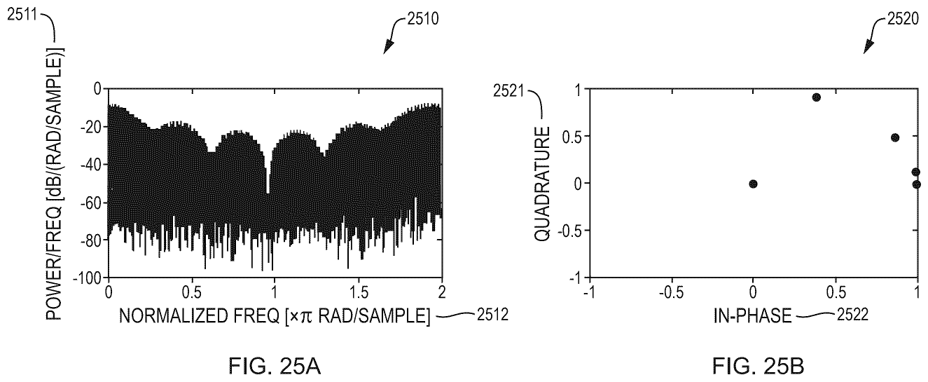

FIGS. 25A and 25B show plots 2510 and 2520, respectively, illustrating radar characterization with Power Spectral Density (PDS) 2510 and constellation plots 2520. Plot 2510 depicts the PSD 2511 of the radar over the normalized frequency 2512. Plot 2520 displays the constellation diagram of the transmitted signal as quadrature 2521 compared to in-phase 2522. The signal lies only in the first quadrant of the IQ plane, which is typical of some radars.

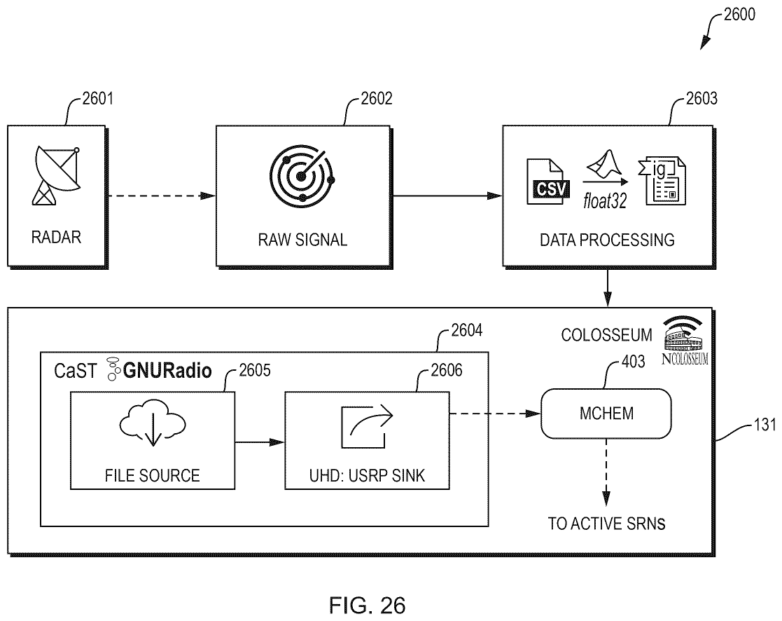

FIG. 26 shows flow diagram 2600 illustrating the various operations developed to integrate an arbitrary waveform (in this case, radar 2601) into the Colosseum environment. In the first step, the radar signal 2602 is generated either through a hardware device or in a synthetic manner. The output of this step 2602 is a raw signal formed of IQ samples for given time instances. The raw data is then processed 2603 to convert it into a format that can be interpreted by Colosseum. The newly created file is transmitted to the Colosseum 131 environment by leveraging the CaST framework 2604, which is based on GNU Radio. For the purpose of this example, CaST has been modified to include a file source block 2605 that allows the user to load the file on the Colosseum system. The signal is then passed through the UHD: USRP Sink block 2606, which connects to the USRP SDR in Colosseum, And transitional over MCHEM 403 to the other SRNs.

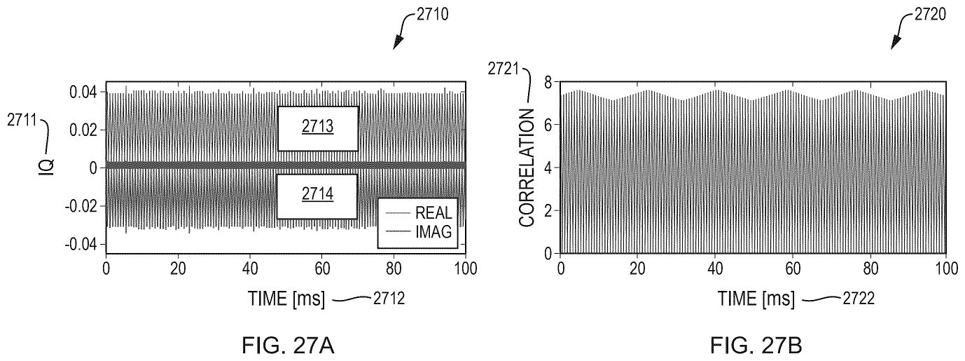

FIGS. 27A and 27B show plots 2710 and 2720, respectively, illustrating the received radar waveform and the radar correlation. Plots 2710 and 2720 show the radar signal transmitted on the Colosseum wireless network emulator through CaST and received by another SRN. Plot 2710 displays real 2713 and imaginary 2714 parts of the raw radar waveform 2711 at the receiver node over time 2712, while plot 2720 displays the correlation 2721 between the original radar signal and the received waveform over time 2722. The correlation 2721 values are clearly visible, meaning that the radar signal is correctly transmitted and detected at the receiver side. A periodic jigsaw trend can be noticed in the correlation results. This behavior is due to the large length of the transmitted radar IQ sequence (106,657 complex points). Upon performing the correlation operation, the length of the sequence causes peaks at the beginning of the sequence, as well as valleys because of the leftover samples from the correlation.

To validate the Waikiki Beach scenario in Colosseum, a novel radio frequency scenario was created that emulates the propagation environment of Waikiki Beach. This scenario involves a base station whose location is taken based off real-world cellular deployments that serves six UEs, and a radar equipped ship that moves in the North Pacific Ocean. This scenario was created with the CaST toolchain following the steps of FIG. 4 discussed above. In the first step, 401, the location scenario is identified period since a ship node is being considered for the radar, the coastal area of Waikiki Beach was chosen. Next at step 402, the 3D model is attained with the selected location. Next, the 3D model is loaded into a ray-tracing program 403, and then the nodes are defined of our scenario as well as their trajectories in step 404.

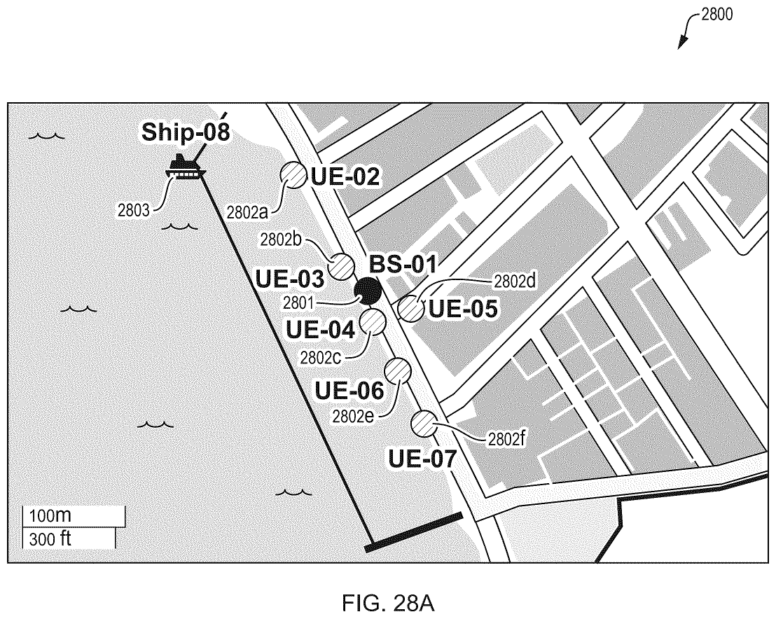

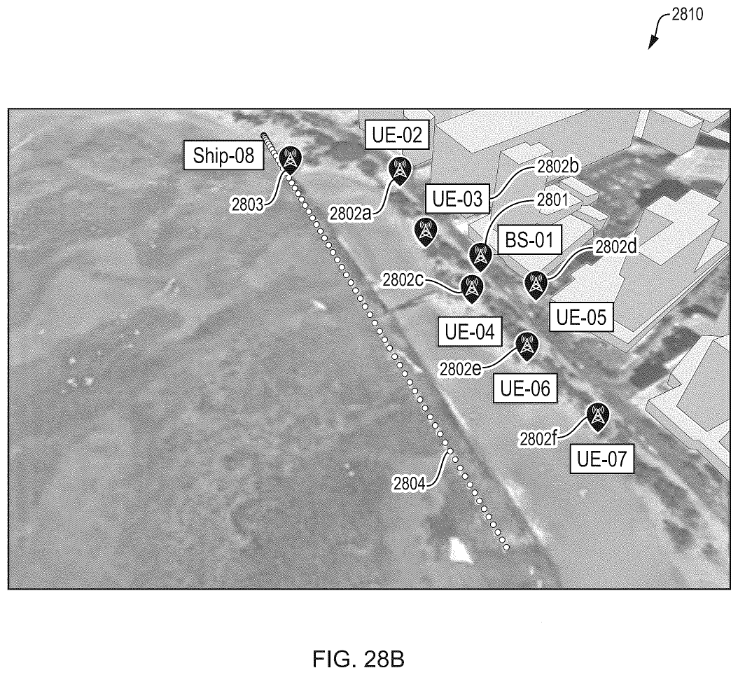

FIG. 28A shows the location of nodes in the Waikiki Beach scenario 2800. This scenario includes one cellular BS 2801 whose antennas are located at three meters from the ground. Also included are six static UEs 2802a-f uniformly distributed in the surroundings of the BS. UEs Are located at 1 m from the ground level to emulate the handheld devices. Further, one ship 2803 equipped with a radar, whose antennas are located at a height of three meters is also included. The ship moves following a North to South linear trajectory along Waikiki Beach at a constant speed of 20 knots (10 m/s). The speed was derived as the average speed between the typical civilian container ships and that of aircraft carriers.

Table 5 below summarizes the wireless parameters defined for the design policy and radio frequency emulation scenario described herein.

TABLE 5

| Parameter | Value | |
|---|---|---|
| Signal Bandwidth | 20 | MHz |
| Transmit Power (BS and ship) | 30 | dBm |
| Transmit Power (UEs) | 20 | dBm |
| Antenna height (BS and ship) | 3 | m |
| Antenna height (UEs) | 1 | m |
| Building Material | Concrete | |
| Max number of reflections | 3 | |
| Sampling time | 1 | second |
| Ship Speed | 10 | m/s |

| | |
|---|---|
| Evaluation Area | 700 × 800 m² |

FIG. 28B shows the layout 2810 of this scenario loaded into the MATLAB ray tracer. Notice the 3D model of the environment, together with the radio node locations, and the trajectory of the ship 2804. In this step, ray-tracing is performed to characterize the environment of interest and to derive the channel taps among each pair of the nodes in this scenario. After these operations are completed, the next step involves approximating the channel taps returned by the ray tracer. This step is required to install the scenario on Coliseum, since the MCHEM supports a maximum of four nonzero channel taps, with a maximum delay spread of 5.12 μs, this is performed through a K-mean clustering algorithm.

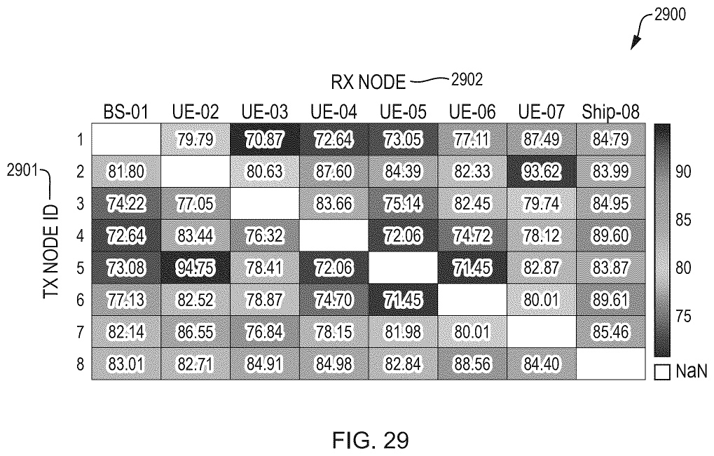

FIG. 29 shows a heat map 2900 of the path loss among each pair of nodes (transceiver nodes 2901 and receiver nodes 2902) after the channel approximation is completed. As expected, closer nodes to the mobile ship node experience lower path loss values.

As the final step, channel taps are converted in FPGA readable format, in this scenario is installed on Colosseum.

The BS station leverages an artificial intelligence model to detect radar signals during or before cellular communications. By using the Waikiki Beach scenario, radar and cellular signals are transmitted in different combinations in varying reception gain. Specifically, IQ samples were collected when only the radar is present, only the cellular signal is present, both are present, neither are present (empty channel). These combinations encompass all the possible real-world scenarios that the intelligent radar detector might come across.

These recordings were preprocessed by first breaking them into small samples of 1024 IQ's, as this is the input size the machine learning agent. This input size was chosen as it was found to be the smallest size that still offered high classification performance. Each sample was then converted to its frequency domain representation. Finally, a binary label was offered to each sample: 1 if radar exists in the sample, and 0 otherwise. In this way, the model groups empty channels and un-interfered cellular transmissions as 0 and therefore free to communicate in the given band.

This scenario was leveraged in Coliseum to deploy a cellular network and run traffic analysis. The parameters of this experiment are listed in Table 6 below.

TABLE 6

| Parameter | Value | |
|---|---|---|
| Center Frequency | 3.6 | GHz |
| Signal Bandwidth (Radar) | 20 | MHz |
| Signal Bandwidth (Cellular) | 10 | MHz |
| Number of BSs | 1 | |
| Number of UEs | 6 | |
| USRP BS gains (Tx and Rx) | [10, 30] | dB |
| USRP UE gains (Tx and Rx) | 20 | dB |
| USRP radar Tx gain | 20 | dB |
| Scenario Duration | 40 | s |
| Traffic Type | UDP Downlink | |
| Traffic Rate | 10 | Mbps |

| | |
|---|---|
| Scheduling Policy | Round-robin |

The center frequency is set to 3.6 GHz in the newly opened CBRS band, which is also used by S-band-type radars. Even though characterized at 3.6 GHz the scenario has been installed in Colosseum at a center frequency of 1 GHz, at which MCHEM is optimized to work. The scenario duration is set to 46 seconds, which is the time needed by the ship to travel the planned 400 m trajectory at the constant speed of 10 m/s. Then, the scenario repeats cyclically from the beginning indefinitely.

The radar signal is transmitted through the use of the CaST transmit node, which has been modified to support custom radio waveforms. In the following, the results are shown for three cellular network use cases. The first is no radar transmission, the second with radar signal interference, and the third with radar and intelligent detector. In all experiments, user datagram protocol downlink traffic of 10 Mbps among BS and UEs is generated.

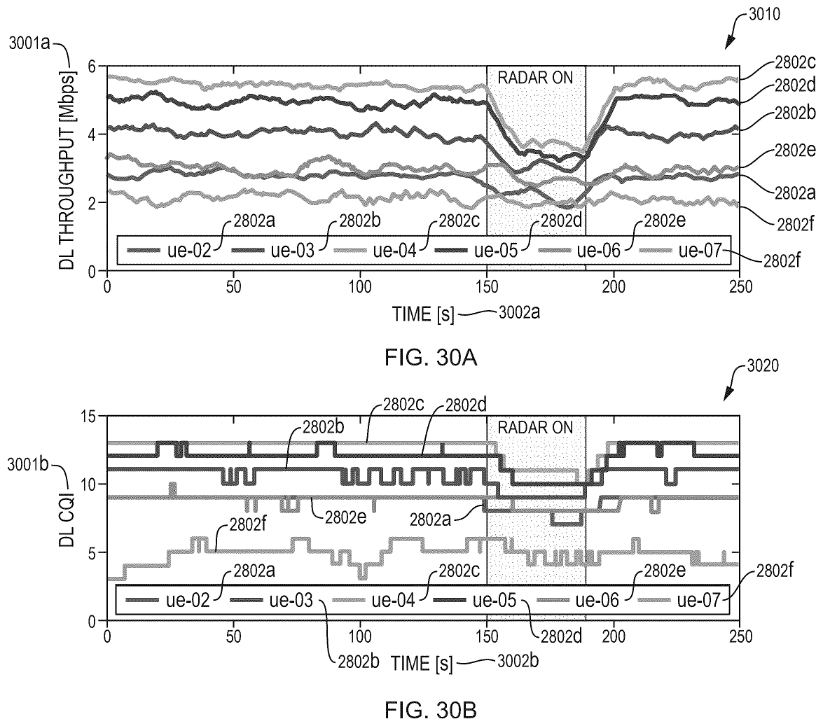

FIGS. 30A and 30B shows plot 3010 and 3020, respectively, illustrating the performance of the cellular network, in terms of downlink throughput 3001a and Channel Quality Indicator (CQI) 3001b, without radar transmissions, from time 3002a-b zero to time 150 (with no radar) for UE-02 2802a, UE-03 2802b, UE-04 2802c, UE-05 2802d, UE-06 2802e and UE-07 2802f. The gains of the BS USRP are set to 25 dB. As expected, the throughput decreases with the increase of the distance between UEs (2802a-f) and BS 2801. The best performance is achieved by UE-04 2802c with values between 5.22 and 5.71 Mbps, while the other UEs experience a performance between 1.82 and 5.25 Mbps. The worst throughput is achieved by UE-07 2802f due to its large distance from the BS 2801, environment conditions, and interference with other nodes. The CQI 3001b follows a similar trend. Best values are reported by UE-04 2802c with a stable CQI of 13. The other UEs show CQI values between 2 and 13, with UE-07 2802f reporting the lowest CQI values between 2 and 7.

With radar, the impact of radar transmissions on the cellular performance can be seen in plots 3010 and 3020 from second 150 to second 190. As expected, a drop in throughput can be noticed as well as a drop in CQI values reported by the UEs. This is more visible for the nodes closer to the BS 2801, e.g., UE-03 2802b, UE-04 2802c, and UE-05 2802d, since they get more affected by the radar transmission. When the radar stops transmitting, i.e., at around second 190, the performance of the UEs goes back to the initial values, i.e., to the values in the [0, 150] second window.

FIG. 31 shows plot 3100 illustrating effectiveness of the detector in understanding the presence of the radar signal. The top portion of plot 3100 shows the downlink cellular spectrogram centered at a frequency 3101 of 980 MHz with a 6 MHz span. The bottom portion plot 3100 illustrates the results of the radar detection system. At the beginning of the experiment, from second (3102) 0 to second 50, the BS is serving the UEs through UDP downlink traffic, as can be seen by the striping 3103a-b. At second 50, a radar transmission is detected by the detector, and the BS is shut down accordingly. After the radar transmission ends, at second 90, the BS receives the command to power back on and, after around 10 seconds, it resumes its operations at second 100. At second 110, the UEs reconnect to the comma and the downlink transmissions are restarted. Overall, this demonstrates the effectiveness of this detector in identifying radar signals and vacating the cellular bandwidth.

### Computer Support

FIG. 32 illustrates a computer network or similar digital processing environment in which embodiments of the present disclosure may be implemented.

Client computer(s)/devices 50 and server computer(s) 60 provide processing, storage, and input/output devices executing application programs and the like. The client computer(s)/devices 50 can also be linked through communications network 70 to other computing devices, including other client devices/processes 50 and server computer(s) 60. The communications network 70 can be part of a remote access network, a global network (e.g., the Internet), a worldwide collection of computers, local area or wide area networks, and gateways that currently use respective protocols (TCP/IP, Bluetooth®, etc.) to communicate with one another. Other electronic device/computer network architectures are suitable.

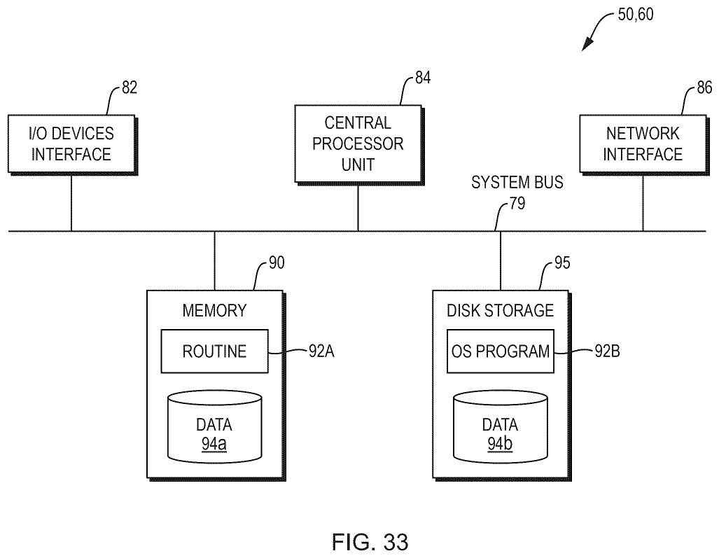

FIG. 33 is a diagram of an example internal structure of a computer (e.g., client processor/device 50 or server computers 60) in the computer system of FIG. 32. Each computer 50, 60 contains a system bus 79, where a bus is a set of hardware lines used for data transfer among the components of a computer or processing system. The system bus 79 is essentially a shared conduit that connects different elements of a computer system (e.g., processor, disk storage, memory, input/output ports, network ports, etc.) that enables the transfer of information between the elements. Attached to the system bus 79 is an I/O device interface 82 for connecting various input and output devices (e.g., keyboard, mouse, displays, printers, speakers, etc.) to the computer 50, 60. A network interface 86 allows the computer to connect to various other devices attached to a network (e.g., network 70 of FIG. 32). Memory 90 provides volatile storage for computer software instructions 92A and data 94a used to implement an embodiment of the present disclosure. The computer software instructions can implement the methods and operations of methods detailed above. Disk storage 95 provides non-volatile storage for computer software instructions 92B and data 94b used to implement an embodiment of the present disclosure. The computer software instructions can implement the methods and operations of methods detailed above. A central processor unit 84 is also attached to the system bus 79 and provides for the execution of computer instructions.

In one embodiment, the processor routines 92A-B and data 94a-b are a computer program product (generally referenced 92), including a non-transitory computer-readable medium (e.g., a removable storage medium such as one or more DVD-ROM's, CD-ROM's, diskettes, tapes, etc.) that provides at least a portion of the software instructions for an embodiment. The computer program product 92 can be installed by any suitable software installation procedure, as is well known in the art. In another embodiment, at least a portion of the software instructions may also be downloaded over a cable communication and/or wireless connection. In other embodiments, the invention programs are a computer program propagated signal product embodied on a propagated signal on a propagation medium (e.g., a radio wave, an infrared wave, a laser wave, a sound wave, or an electrical wave propagated over a global network such as the Internet, or other network(s)). Such carrier medium or signals may be employed to provide at least a portion of the software instructions for the present invention routines/program 92A-B.

Embodiments or aspects thereof may be implemented in the form of hardware, firmware, or software. If implemented in software, the software may be stored on any non-transient computer readable medium that is configured to enable a processor to load the software or subsets of instructions thereof. The processor then executes the instructions and is configured to operate or cause an apparatus to operate in a manner as described herein.

Further, firmware, software, routines, or instructions may be described herein as performing certain actions and/or functions of the data processors. However, it should be appreciated that such descriptions contained herein are merely for convenience and that such actions in fact result from computing devices, processors, controllers, or other devices executing the firmware, software, routines, instructions, etc.

It should be understood that the flow diagrams, block diagrams, and network diagrams may include more or fewer elements, be arranged differently, or be represented differently. But it further should be understood that certain implementations may dictate the block and network diagrams and the number of block and network diagrams illustrating the execution of the embodiments be implemented in a particular way.

Accordingly, further embodiments may also be implemented in a variety of computer architectures, physical, virtual, cloud computers, and/or some combination thereof, and thus, the data processors described herein are intended for purposes of illustration only and not as a limitation of the embodiments.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A computer-implemented system for representing a wireless communications network, the system comprising:
a digital twinning platform comprising a real-world twin component and a virtual-world twin component representing at least a matching subset of layers of a full stack wireless communications network; and
a communications module configured to enable bi-directional flow of data representing state information corresponding to the subset of layers of the real-world component and the virtual-world component.

2. The computer-implemented system of claim 1, wherein the digital twinning platform includes a modeler configured to generate a model to represent the wireless communications network.

3. The computer-implemented system of claim 2, wherein the generated model includes: (i) representations of physical surfaces defining a real-world environment of the wireless communications network, and (ii) nodal representations of at least a subset of transmitters, receivers, or transceivers composing the wireless communications network.

4. The computer-implemented system of claim 3, wherein the generated model is further configured by the system to be:
loaded into a ray-tracing program, the ray-tracing program further configured to:
assign material properties to at least a subset of the representations of physical surfaces; and
model the nodal representations and define trajectories of at least a subset of radio frequencies associated with the nodal representations.

5. The computer-implemented system of claim 2, further comprising a graphical user interface (GUI) or an application programming interface (API) configured to enable a user to perform a simulation of channel environments within the digital twin virtual-component of the wireless communications network.

6. The computer-implemented system of claim 5, wherein the simulation includes at least one controllable parameter within the virtual-world twin component, the GUI and API further configured to push the controllable parameter from the virtual-world twin component to the real-world physical twin component.

7. The computer-implemented system of claim 1, wherein the communications module enables the bi-directional data flow between the real-world physical twin component and the virtual-world twin component to occur in real time.

8. The computer-implemented system of claim 1, further comprising a socket configured to enable at least one feature or part of a real-world device to stand in place of at least one corresponding feature or part of the virtual-world component.

9. The computer-implemented system of claim 1, wherein the digital twinning platform is further configured to:
track at least one control system configured to host or run a computer code related to a protocol for the full stack wireless communications network;
provide at least one pipeline configured to replicate a software built in the virtual-world twin component and real-world physical twin component; and
generate the virtual-world twin component representing a corresponding subset of layers of the full stack wireless communications network from the tracked at least one control system and the provided at least one pipeline.

10. The computer-implemented system of claim 9, wherein the at least one pipeline enables real-time testing of at least one virtual-world component simulation parameter in the real-world twin component, or real-time testing of at least one real-world physical component parameter in the virtual-world twin component.

11. A computer-implemented method for representing a wireless communications network, the method comprising:
twinning a real-world wireless communications network via a digital twinning platform, the digital twinning platform comprising a real-world twin component and a virtual-world twin component representing at least a matching subset of layers of a full stack wireless communications network; and
enabling bi-directional flow of data representing state information, via a communications module, corresponding to the subset of layers of the real-world component and the virtual-world component.

12. The computer-implemented method of claim 11, wherein the digital twinning platform further comprises generating a model to represent the wireless communications network.

13. The computer-implemented method of claim 12, wherein the generating the model further comprises: (i) generating and modeling representations of physical surfaces defining a real-world environment of the wireless communications network, and (ii) generating and modeling nodal representations of at least a subset of transmitters, receivers, or transceivers composing the wireless communications network.

14. The computer-implemented method of claim 13, further comprising:
loading the generated model into a ray-tracing program, the ray-tracing program comprising:
assigning material properties to at least a subset of the representations of physical surfaces; and
modeling the nodal representations and defining trajectories of at least a subset of radio frequencies associated with the nodal representations.

15. The computer-implemented method of claim 12, further comprising performing a simulation of channel environments within the digital twin virtual-component of the wireless communications network, via a graphical user interface (GUI) or an application programming interface (API).

16. The computer-implemented method of claim 15, wherein the simulation includes:
controlling at least one parameter within the virtual-world twin component; and
pushing the controllable parameter from the virtual-world twin component to the real-world physical twin component via the GUI and API.

17. The computer-implemented method of claim 11, wherein the communications module further comprises enabling the bi-directional data flow between the real-world physical twin component and the virtual-world twin component to occur in real time.

18. The computer-implemented method of claim 11, further comprising enabling, via a socket, at least one feature or part of a real-world device to stand in place of at least one corresponding feature or part of the virtual-world component.

19. The computer-implemented method of claim 11, wherein the digital twinning platform further comprises:
tracking at least one control system configured to host or run a computer code related to a protocol for the full stack wireless communications network;
providing at least one pipeline configured to replicate a software built in the virtual-world twin component and real-world physical twin component; and
generating the virtual-world twin component representing a corresponding subset of layers of the full stack wireless communications network from the tracked at least one control system and the provided at least one pipeline.

20. The computer-implemented method of claim 19, further comprising testing in real-time, via the at least one pipeline, at least one virtual-world component simulation parameter in the real-world twin component, or testing in real-time at least one real-world physical component parameter in the virtual-world twin component.
